(19) United States
(12) Patent Application Publication
(10) Pub. No.: US 2024/0282657 A1
(43) Pub. Date: Aug. 22, 2024

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/652,836

(22) Filed: May 2, 2024

Related U.S. Application Data
(63) Continuation of application No. PCT/JP2022/040496, filed on Oct. 28, 2022.

(30) Foreign Application Priority Data
Nov. 5, 2021 (JP) 2021-181316

(51) Int. Cl. H01L 23/31; H01L 23/00; H01L 23/29

(52) U.S. Cl. CPC H01L 23/3157; H01L 23/295; H01L 24/29; H01L 2224/29007

(57) ABSTRACT

A semiconductor device includes a chip that has a main surface, a main surface electrode that is arranged on the main surface, a terminal electrode that is arranged on the main surface electrode such as to expose a part of the main surface electrode; and a sealing insulator that covers a periphery of the terminal electrode such as to expose a part of the terminal electrode, and that has a portion directly covering the main surface electrode.

### CROSS-REFERENCE TO RELATED APPLICATIONS

The present application is a bypass continuation of International Patent Application No. PCT/JP2022/040496 filed on Oct. 28, 2022, which claims the benefit of priority to Japanese Patent Application No. 2021-181316 filed on Nov. 5, 2021, the entire contents of each application are hereby incorporated herein by reference.

### BACKGROUND

### 1. Field of the Disclosure

The present disclosure relates to a semiconductor device.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is a cross sectional view taken along III-III line shown in FIG. 1.

FIG. 4 is an enlarged plan view showing a principal part of an inner portion of a chip.

FIG. 5 is a cross sectional view taken along V-V line shown in FIG. 4.

FIG. 6 is an enlarged cross sectional view showing a peripheral edge portion of the chip.

FIG. 7 is a plan view showing layout examples of a gate electrode and a source electrode.

FIG. 8 is a cross sectional view showing a main part of a gate terminal electrode shown in FIG. 3.

FIG. 9 is a cross sectional view showing a main part of a source terminal electrode shown in FIG. 3.

FIG. 10 is a plan view showing a wafer structure that is to be used at a time of manufacturing.

FIG. 11 is a cross sectional view showing a device region shown in FIG. 10.

FIGS. 12A to 12I are cross sectional views showing a manufacturing method example for the semiconductor device shown in FIG. 1.

FIG. 13 is a cross sectional view showing a semiconductor device according to a second embodiment.

FIG. 14 is a cross sectional view showing a main part of a gate terminal electrode shown in FIG. 13.

FIG. 15 is a cross sectional view showing a main part of a source terminal electrode shown in FIG. 13.

FIG. 16 is a plan view showing a layout example of an upper insulating film shown in FIG. 13.

FIGS. 17A and 17B are cross sectional views showing a manufacturing method example for the semiconductor device shown in FIG. 13.

FIG. 18 is a cross sectional view showing a semiconductor device according to a third embodiment.

FIGS. 19A and 19B are cross sectional views showing a manufacturing method example for the semiconductor device shown in FIG. 18.

FIG. 20 is a cross sectional view showing a semiconductor device according to a fourth embodiment.

FIG. 21 is a cross sectional view showing a gate terminal electrode shown in FIG. 20.

FIG. 22 is a cross sectional view showing a gate terminal electrode shown in FIG. 20.

FIG. 23 is a plan view showing a layout example of an upper insulating film shown in FIG. 20.

FIG. 24 is a plan view showing a semiconductor device according to a fifth embodiment.

FIG. 25 is a plan view showing a semiconductor device according to a sixth embodiment.

FIG. 26 is a cross sectional view taken along XXVI-XXVI line shown in FIG. 25.

FIG. 27 is a circuit diagram showing an electrical configuration of the semiconductor device shown in FIG. 25.

FIG. 28 is a plan view showing a semiconductor device according to a seventh embodiment.

FIG. 29 is a cross sectional view taken along XXIX-XXIX line shown in FIG. 28.

FIG. 30 is a plan view showing a semiconductor device according to an eighth embodiment.

FIG. 31 is a plan view showing a semiconductor device according to a ninth embodiment.

FIG. 32 is a plan view showing a semiconductor device according to a tenth embodiment.

FIG. 33 is a plan view showing a semiconductor device according to an eleventh embodiment.

FIG. 34 is a cross sectional view taken along XXXIV-XXXIV line shown in FIG. 33.

FIG. 35 is a plan view showing a semiconductor device according to a twelfth embodiment.

FIG. 36 is a plan view showing a semiconductor device according to a thirteenth embodiment.

FIG. 37 is a plan view showing a semiconductor device according to a fourteenth embodiment.

FIG. 38 is a cross sectional view showing a modified example of the chip to be applied to each of the embodiments.

FIG. 39 is a cross sectional view showing a modified example of a sealing insulator to be applied to each of the embodiments having the upper insulating film.

FIG. 40 is a plan view showing a package to which any one of the semiconductor devices according to the first to tenth embodiments is to be incorporated.

FIG. 41 is a plan view showing a package to which any one of the semiconductor devices according to the eleventh to fourteenth embodiments is to be incorporated.

FIG. 42 is a perspective view showing a package to which any one of the semiconductor devices according to the first to tenth embodiments and any one of the semiconductor devices according to eleventh to fourteenth embodiments are to be incorporated.

FIG. 43 is an exploded perspective view of the package shown in FIG. 42.

FIG. 44 is a cross sectional view taken along XLIV-XLI line shown in FIG. 42.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

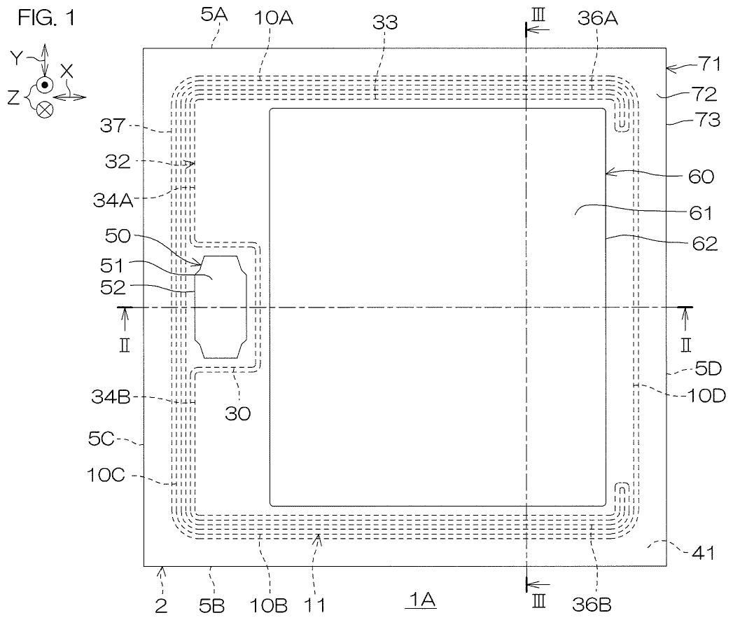

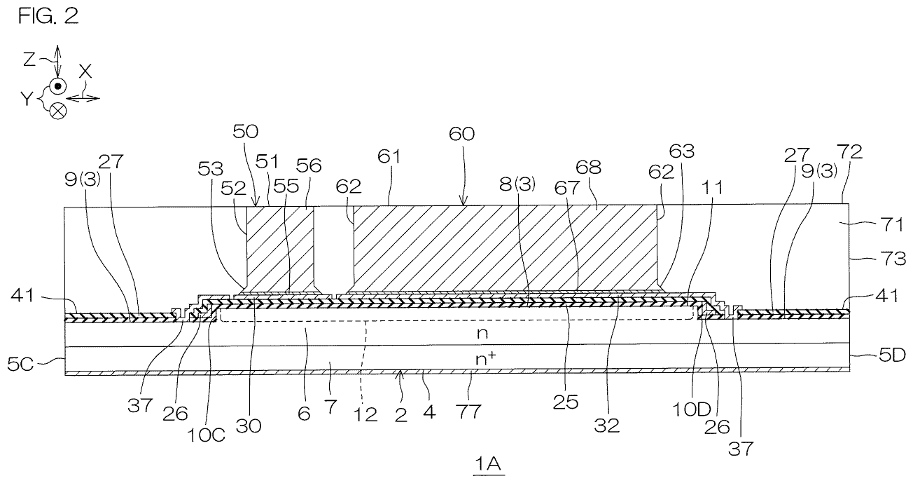

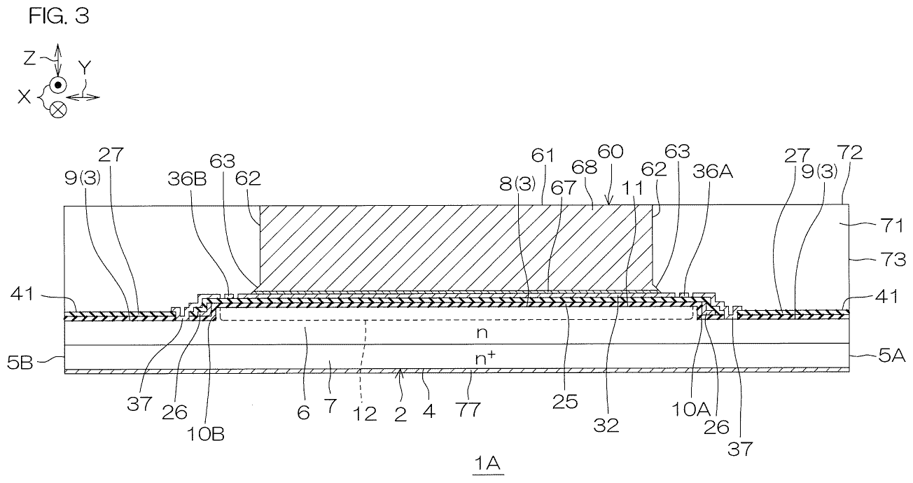

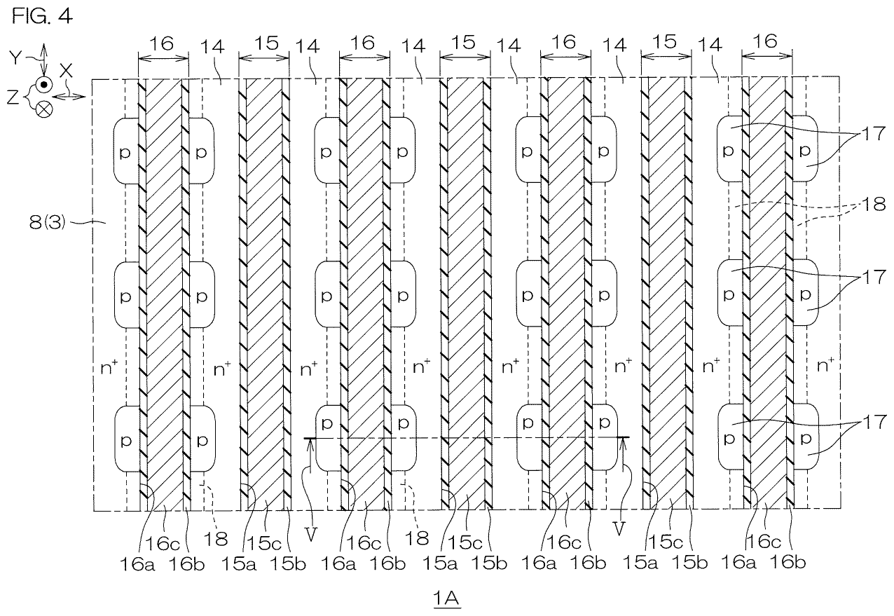

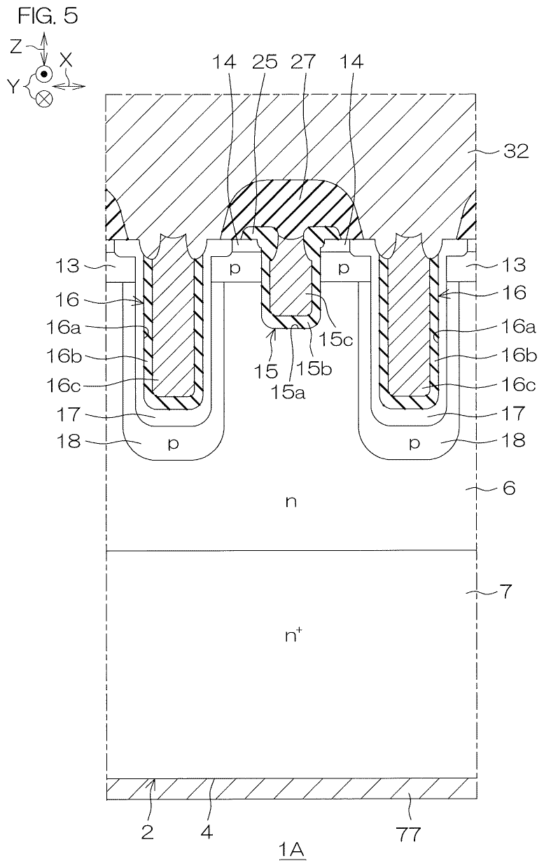

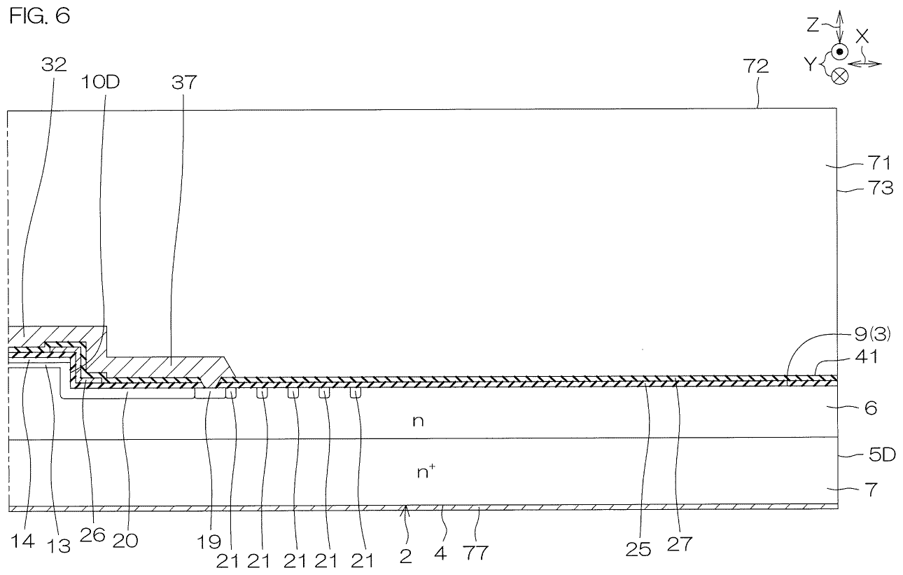

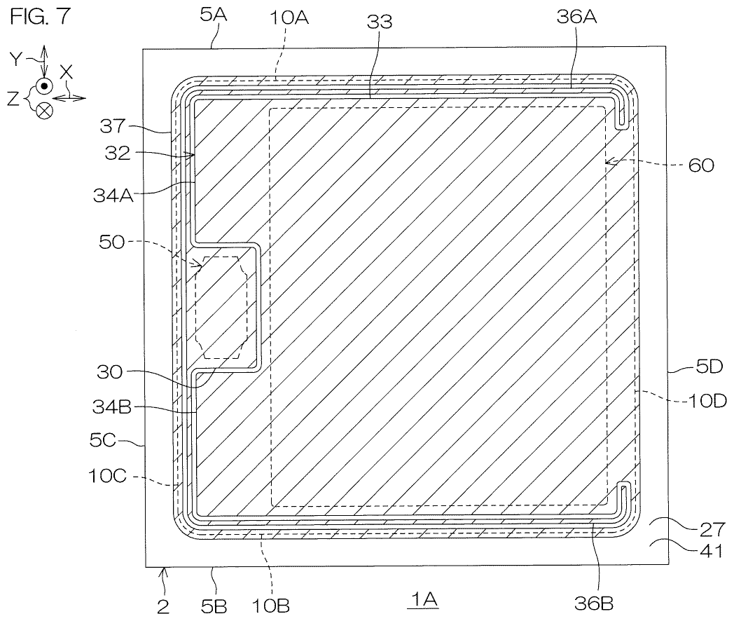

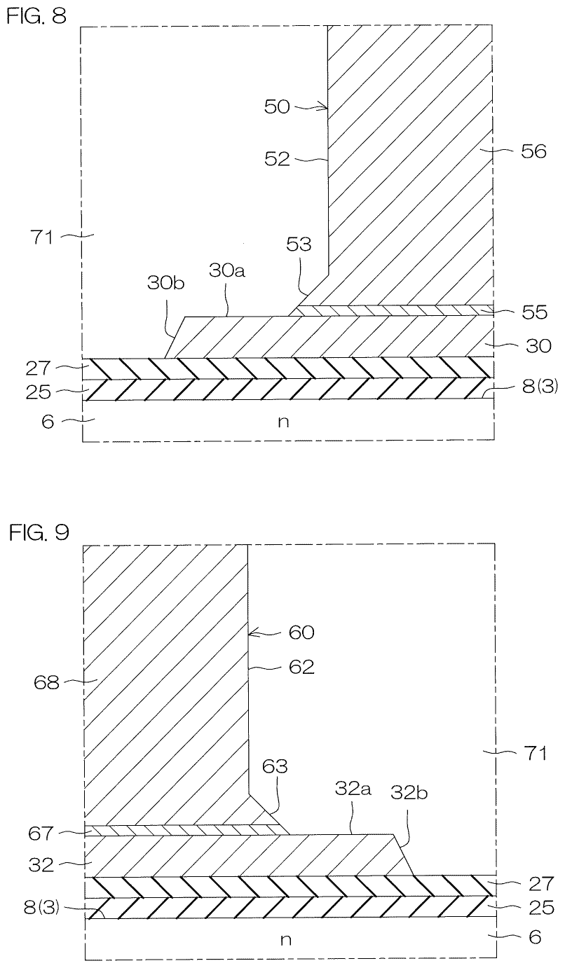

FIG. 1 is a plan view of a semiconductor device 1A according to a first embodiment. FIG. 2 is a cross sectional view taken along II-II line shown in FIG. 1. FIG. 3 is a cross sectional view taken along III-III line shown in FIG. 1. FIG. 4 is an enlarged plan view showing a principal part of an inner portion of a chip 2. FIG. 5 is a cross sectional view taken along V-V line shown in FIG. 4. FIG. 6 is an enlarged cross sectional view showing a peripheral edge portion of the chip 2. FIG. 7 is a plan view showing layout examples of a gate electrode 30 and a source electrode 32. FIG. 8 is a cross sectional view showing a main part of a gate terminal electrode 50 shown in FIG. 3. FIG. 9 is a cross sectional view showing a main part of a source terminal electrode 60 shown in FIG. 3.

With reference to FIG. 1 to FIG. 9, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11-20] direction) of the SiC monocrystal. The off angle may be more than 0° and not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm, in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2 and FIG. 3, the MISFET structure 12 is shown simplified by a dashed line. Hereinafter, with reference to FIG. 4 and FIG. 5, a specific structure of the MISFET structure 12 shall be described. The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 6, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 has a gate electrode surface 30a and a gate electrode side wall 30b. The gate electrode surface 30a flatly extends along the interlayer insulating film 27. The gate electrode side wall 30b is positioned on the interlayer insulating film 27. The gate electrode side wall 30b may extend in a manner obliquely inclined or substantially vertical with respect to the interlayer insulating film 27. As a matter of course, the gate electrode side wall 30b may extend in a curved sagging manner from the gate electrode surface 30a toward the interlayer insulating film 27.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate lower conductor layer 31 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

With reference to FIG. 9, the source electrode 32 has a source electrode surface 32a and a source electrode side wall 32b. The source electrode surface 32a flatly extends along the interlayer insulating film 27. The source electrode side wall 32b is positioned on the interlayer insulating film 27. The source electrode side wall 32b may extend in a manner obliquely inclined or substantially vertical with respect to the interlayer insulating film 27. As a matter of course, the source electrode side wall 32b may extend in a curved sagging manner from the source electrode surface 32a toward the interlayer insulating film 27.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 may include at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably include the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably includes the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 on the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes a dicing street 41 provided in a region between the peripheral edge of the first main surface 3 and the source wiring 37. Specifically, the dicing street 41 is provided in a region between the peripheral edge of the first main surface 3 and the outermost field regions 21. The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment.

The dicing street 41 exposes the interlayer insulating film 27, in this embodiment. As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

With reference to FIG. 3 and FIG. 8, the semiconductor device 1A includes a gate terminal electrode 50 that is arranged on the gate electrode 30. The gate terminal electrode 50 is erected in a columnar shape on the gate electrode 30. The gate terminal electrode 50 has an area less than the area of the gate electrode 30 in plan view and is arranged on the inner portion of the gate electrode 30 at an interval from the peripheral edge of the gate electrode 30. That is, the gate terminal electrode 50 exposes at least a part of a corner portion (peripheral edge portion) of the gate electrode 30.

The gate terminal electrode 50 exposes the corner portion of the gate electrode 30 over the entire circumference, in this embodiment. The gate terminal electrode 50 specifically exposes the gate electrode surface 30a and the gate electrode side wall 30b at the corner portion of the gate electrode 30. The gate terminal electrode 50 has a lower end that is only connected to the gate electrode surface 30a on the gate electrode 30.

The gate terminal electrode 50 has a gate terminal surface 51 and a gate terminal side wall 52. The gate terminal surface 51 flatly extends along the first main surface 3. The gate terminal surface 51 may consist of a ground surface with grinding marks. The gate terminal side wall 52 is positioned on the gate electrode 30 and extends substantially vertically to the normal direction Z. Here, “substantially vertically” includes a mode that extends in the laminate direction while being curved (meandering). The gate terminal side wall 52 preferably consists of a smooth surface without a grinding mark.

The gate terminal electrode 50 has a first protrusion portion 53 that outwardly protrudes at a lower end portion of the gate terminal side wall 52. The first protrusion portion 53 is formed at a region on the gate electrode 30 side than an intermediate portion of the gate terminal side wall 52. The first protrusion portion 53 extends along the gate electrode surface 30a of the gate electrode 30, and is formed in a tapered shape in which a thickness gradually decreases toward the tip portion from the gate terminal side wall 52 in cross sectional view. The first protrusion portion 53 therefore has a sharp-shaped tip portion with an acute angle. As a matter of course, the gate terminal electrode 50 without the first protrusion portion 53 may be formed.

The gate terminal electrode 50 preferably has a thickness exceeding the thickness of the gate electrode 30. The thickness of the gate terminal electrode 50 is defined by a distance between the gate electrode surface 30a and the gate terminal surface 51. The thickness of the gate terminal electrode 50 exceeds the thickness of the chip 2, in this embodiment. As a matter of course, the thickness of the gate terminal electrode 50 may be less than the thickness of the chip 2. The thickness of the gate terminal electrode 50 may be not less than 10 μm and not more than 300 μm. The thickness of the gate terminal electrode 50 is preferably not less than 30 μm. The thickness of the gate terminal electrode 50 is particularly preferably not less than 80 μm and not more than 200 μm.

A planar area of the gate terminal electrode 50 is to be adjusted in accordance with the planar area of the first main surface 3. The planar area of the gate terminal electrode 50 is defined by a planar area of the gate terminal surface 51. The planar area of the gate terminal electrode 50 is preferably not more than 25% of the first main surface 3. The planar area of the gate terminal electrode 50 may be not more than 10% of the first main surface 3.

When the first main surface 3 has the planar area of not less than 1 mm square, the planar area of the gate terminal electrode 50 may be not less than 0.4 mm square. The gate terminal electrode 50 may be formed in a polygonal shape (for example, rectangular shape) having a planar area of not less than 0.4 mm×0.7 mm. The gate terminal electrode 50 is formed in a polygonal shape (quadrangle shape with four corners cut out in a rectangular shape) having four sides parallel to the first to fourth side surfaces 5A to 5D in plan view, in this embodiment. As a matter of course, the gate terminal electrode 50 may be formed in a quadrangle shape, a polygonal shape other than the quadrangle shape, a circular shape, or an elliptical shape in plan view.

The gate terminal electrode 50 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape. The first gate conductor film 55 forms a part of the first protrusion portion 53. The first gate conductor film 55 does not necessarily have to be formed and may be omitted.

The second gate conductor film 56 forms a body of the gate terminal electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 exceeds the thickness of the chip 2, in this embodiment.

The second gate conductor film 56 covers the gate electrode 30 with the first gate conductor film 55 interposed therebetween. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a source terminal electrode 60 that is arranged on the source electrode 32. The source terminal electrode 60 is erected in a columnar shape on the source electrode 32. The source terminal electrode 60 may have an area less than the area of the source electrode 32 in plan view, and may be arranged on an inner portion of the source electrode 32 at an interval from the peripheral edge of the source electrode 32. That is, the source terminal electrode 60 exposes at least a part of a corner portion (peripheral edge portion) of the source electrode 32.

The source terminal electrode 60 exposes the corner portion of the source electrode 32 over the entire circumference in plan view, in this embodiment. The source terminal electrode 60 specifically exposes the source electrode surface 32a and the source electrode side wall 32b at the corner portion of the source electrode 32. The source terminal electrode 60 has a lower end that is only connected to the source electrode surface 32a on the source electrode 32.

The source terminal electrode 60 is arranged on the body electrode portion 33 of the source electrode 32, and is not arranged on the drawer electrode portions 34A, 34B of the source electrode 32, in this embodiment. A facing area between the gate terminal electrode 50 and the source terminal electrode 60 is thereby reduced.

Such a structure is effective in reducing a risk of short-circuit between the gate terminal electrode 50 and the source terminal electrode 60, in a case in which conductive adhesives such as solders and metal pastes are to be adhered to the gate terminal electrode 50 and the source terminal electrode 60. As a matter of course, conductive bonding members such as conductor plates and conducting wires (for example, bonding wires) may be connected to the gate terminal electrode 50 and the source terminal electrode 60. In this case, a risk of short-circuit between the conductive bonding member on the gate terminal electrode 50 side and the conductive bonding member on the source terminal electrode 60 side can be reduced.

The source terminal electrode 60 has a source terminal surface 61 and a source terminal side wall 62. The source terminal surface 61 flatly extends along the first main surface 3. The source terminal surface 61 may consist of a ground surface with grinding marks. The source terminal side wall 62 is located on the source electrode 32 and extends substantially vertically to the normal direction Z. Here, “substantially vertically” includes a mode that extends in the laminate direction while being curved (meandering). The source terminal side wall 62 preferably consists of a smooth surface without a grinding mark.

The source terminal electrode 60 has a second protrusion portion 63 that outwardly protrudes at a lower end portion of the source terminal side wall 62. The second protrusion portion 63 is formed at a region on the source electrode 32 side than an intermediate portion of the source terminal side wall 62. The second protrusion portion 63 extends along the source electrode surface 32a of the source electrode 32, and is formed in a tapered shape in which a thickness gradually decreases toward the tip portion from the source terminal side wall 62 in cross sectional view. The second protrusion portion 63 therefore has a sharp-shaped tip portion with an acute angle. As a matter of course, the source terminal electrode 60 without the second protrusion portion 63 may be formed.

The source terminal electrode 60 preferably has a thickness exceeding the thickness of the source electrode 32. The thickness of the source terminal electrode 60 is defined by a distance between the source electrode surface 32a and the source terminal surface 61. The thickness of the source terminal electrode 60 exceeds the thickness of the chip 2, in this embodiment. As a matter of course, the thickness of the source terminal electrode 60 may be less than the thickness of the chip 2. The thickness of the source terminal electrode 60 may be not less than 10 μm and not more than 300 μm. The thickness of the source terminal electrode 60 is preferably not less than 30 μm. The thickness of the source terminal electrode 60 is particularly preferably not less than 80 μm and not more than 200 μm. The thickness of the source terminal electrode 60 is substantially equal to the thickness of the gate terminal electrode 50.

A planar area of the source terminal electrode 60 is to be adjusted in accordance with the planar area of the first main surface 3. The planar area of the source terminal electrode 60 is defined by a planar area of the source terminal surface 61. The planar area of the source terminal electrode 60 preferably exceeds the planar area of the gate terminal electrode 50. The planar area of the source terminal electrode 60 is preferably not less than 50% of the first main surface 3. The planar area of the source terminal electrode 60 is particularly preferably not less than 75% of the first main surface 3.

In a case in which the first main surface 3 has a planar area of not less than 1 mm square, the planar area of the source terminal electrode 60 is preferably not less than 0.8 mm square. In this case, the planar area of each of the source terminal electrode 60 is particularly preferably not less than 1 mm square. The source terminal electrode 60 may be formed in a polygonal shape having a planar area of not less than 1 mm×1.4 mm. The source terminal electrode 60 is formed in a quadrangle shape having four sides parallel to the first to fourth side surfaces 5A to 5D in plan view, in this embodiment. As a matter of course, the source terminal electrode 60 may be formed in a polygonal shape other than the quadrangle shape, a circular shape, or an elliptical shape in plan view.

The source terminal electrode 60 has a laminated structure that includes a first source conductor film 67 and a second source conductor film 68 laminated in that order from the source electrode 32 side, in this embodiment. The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material of that of the first gate conductor film 55.

The first source conductor film 67 has a thickness less than the thickness of the source electrode 32. The first source conductor film 67 covers the source electrode 32 in a film shape. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source terminal electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material as that of the second gate conductor film 56. The second source conductor film 68 preferably has a thickness exceeding the thickness of the source electrode 32. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the source electrode 32 with the first source conductor film 67 interposed therebetween. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The semiconductor device 1A includes a sealing insulator 71 that covers the first main surface 3. The sealing insulator 71 covers a periphery of the gate terminal electrode 50 and a periphery of the source terminal electrode 60 such as to expose a part of the gate terminal electrode 50 and a part of the source terminal electrode 60 on the first main surface 3. Specifically, the sealing insulator 71 covers the active surface 8, the outer surface 9 and the first to fourth connecting surfaces 10A to 10D such as to expose the gate terminal electrode 50 and the source terminal electrode 60.

The sealing insulator 71 exposes the gate terminal surface 51 and the source terminal surface 61 and covers the gate terminal side wall 52 and the source terminal side wall 62. The sealing insulator 71 covers the first protrusion portion 53 of the gate terminal electrode 50 and faces the gate electrode 30 with the first protrusion portion 53 interposed therebetween, in this embodiment. The sealing insulator 71 suppresses a dropout of the gate terminal electrode 50. Also, the sealing insulator 71 covers the second protrusion portion 63 of the source terminal electrode 60 and faces the source electrode 32 with the second protrusion portion 63 interposed therebetween, in this embodiment. The sealing insulator 71 suppresses a dropout of the source terminal electrode 60.

With reference to FIG. 8, the sealing insulator 71 has a portion that directly covers the gate electrode 30 on a lower end portion side of the gate terminal electrode 50. Specifically, the sealing insulator 71 has a portion that directly covers at least a part of a corner portion of the gate electrode 30. The sealing insulator 71 directly covers the whole region of the corner portion of the gate electrode 30, in this embodiment.

The sealing insulator 71 directly covers the gate electrode surface 30a and the gate electrode side wall 30b at the corner portion of the gate electrode 30. That is, the sealing insulator 71 has a portion in contact only with the gate electrode 30 (the gate electrode surface 30a) and the gate terminal electrode 50 (the gate terminal side wall 52) immediately above the gate electrode 30. A portion of the sealing insulator 71 that directly covers the gate electrode side wall 30b is in contact with the interlayer insulating film 27.

With reference to FIG. 9, the sealing insulator 71 has a portion that directly covers the source electrode 32 on a lower end portion side of the source terminal electrode 60. Specifically, the sealing insulator 71 has a portion that directly covers at least a part of a corner portion of the source electrode 32. The sealing insulator 71 directly covers the whole region of the corner portion of the source electrode 32, in this embodiment.

The sealing insulator 71 directly covers the source electrode surface 32a and the source electrode side wall 32b at the corner portion of the source electrode 32. That is, the sealing insulator 71 has a portion in contact only with the source electrode 32 (the source electrode surface 32a) and the source terminal electrode 60 (the source terminal side wall 62) immediately above the source electrode 32. A portion of the sealing insulator 71 that directly covers the source electrode side wall 32b is in contact with the interlayer insulating film 27.

The sealing insulator 71 directly covers the whole region of the plurality of gate wirings 36A, 36B and the whole region of the source wiring 37. According to this, the sealing insulator 71 electrically insulates the gate terminal electrode 50 and the source terminal electrode 60 from each other, and electrically insulates the gate electrode 30 and the source electrode 32 from each other at the same time.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 51 and the source terminal surface 61. The insulating main surface 72 may consist of a ground surface with grinding marks. In this case, the insulating main surface 72 preferably forms a single ground surface with the gate terminal surface 51 and the source terminal surface 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 50 and the thickness of the source terminal electrode 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include the plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32. The particle sizes of the medium size fillers may be not less than 1 μm and not more than 20 μm.

The plurality of fillers may have thicknesses exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The sealing insulator 71 may include a plurality of filler fragments each having a broken particle shape in a surface layer portion of the insulating main surface 72 and in a surface layer portion of the insulating side wall 73. The plurality of filler fragments may each be formed by any one of a part of the small size fillers, a part of the medium size fillers and a part of the large size fillers.

The plurality of filler fragments positioned on the insulating main surface 72 side each has a broken portion that is formed along the insulating main surface 72 such as to be oriented to the insulating main surface 72. The plurality of filler fragments positioned on the insulating side wall 73 side each has a broken portion that is formed along the insulating side wall 73 such as to be oriented to the insulating side wall 73. The broken portions of the plurality of filler fragments may be exposed from the insulating main surface 72 and the insulating side wall 73, or may be partially or wholly covered with the matrix resin. The plurality of filler fragments do not affect the structures on the chip 2 side, since the plurality of filler fragments are located in the surface layer portions of the insulating main surface 72 and the insulating side wall 73.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 60 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the gate electrode 30 (the main surface electrode), the gate terminal electrode 50, and the sealing insulator 71. The chip 2 has the first main surface 3. The gate electrode 30 is arranged on the first main surface 3. The gate terminal electrode 50 is arranged on the gate electrode 30 such as to expose a part of the gate electrode 30. The sealing insulator 71 covers the periphery of the gate terminal electrode 50 such as to expose a part of the gate terminal electrode 50, and has the portion that directly covers the gate electrode 30.

In accordance with the structure above, since no other member is interposed between the gate electrode 30 and the sealing insulator 71, the starting points for peel-off between the gate electrode 30 and the sealing insulator 71 can be reduced. This allows the sealing insulator 71 to adequately protect a sealing target (e.g. the gate electrode 30). That is, it is possible to protect the sealing target from damage due to an external force and/or degradation due to moisture. This allows for shape defects and variations in the electrical properties to be suppressed. It is therefore possible to provide the semiconductor device 1A capable of improving reliability.

From another point of view, the semiconductor device 1A includes the chip 2, the source electrode 32 (the main surface electrode), the source terminal electrode 60, and the sealing insulator 71. The chip 2 has the first main surface 3. The source electrode 32 is arranged on the first main surface 3. The source terminal electrode 60 is arranged on the source electrode 32 such as to expose a part of the source electrode 32. The sealing insulator 71 covers the periphery of the source terminal electrode 60 such as to expose a part of the source electrode 32, and has the portion that directly covers the source electrode 32.

In accordance with the structure above, since no other member is interposed between the source electrode 32 and the sealing insulator 71, the starting points for peel-off between the source electrode 32 and the sealing insulator 71 can be reduced. This allows the sealing insulator 71 to adequately protect a sealing target (e.g. the source electrode 32). That is, it is possible to protect the sealing target from damage due to an external force and/or degradation due to moisture. This allows for shape defects and variations in the electrical properties to be suppressed. It is therefore possible to provide the semiconductor device 1A capable of improving reliability.

It is preferable that the gate terminal electrode 50 (the source terminal electrode 60) exposes the corner portion of the gate electrode 30 (the source electrode 32), and that the sealing insulator 71 directly covers at least a part of the corner portion of the gate electrode 30 (the source electrode 32). That is, it is preferable that the gate terminal electrode 50 (the source terminal electrode 60) exposes the gate electrode surface 30a (the source electrode surface 32a) and the gate electrode side wall 30b (the source electrode side wall 32b), and that the sealing insulator 71 directly covers the gate electrode surface 30a (the source electrode surface 32a) and the gate electrode side wall 30b (the source electrode side wall 32b).

In accordance with the structure above, it is possible to reduce the peel-off starting points at the corner portion of the gate electrode 30 (the source electrode 32), and to suppress ingress of moisture or the like starting at the corner portion of the gate electrode 30 (the source electrode 32). The sealing insulator 71 preferably has the portion in contact only with the gate electrode 30 (the source electrode 32) and the gate terminal electrode 50 (the source terminal electrode 60). The sealing insulator 71 is preferably thicker than the gate electrode 30 (the source electrode 32). It is particularly preferable that the sealing insulator 71 is thicker than the chip 2.

Those above structures are effective when the gate terminal electrode 50 (the source terminal electrode 60) having a relatively large planar area and/or a relatively large thickness is applied to the chip 2 having a relatively large planar area and/or a relatively small thickness. The gate terminal electrode 50 (the source terminal electrode 60) having the relatively large planar area and/or the relatively large thickness is also effective in absorbing a heat generated on the chip 2 side and dissipating the heat to the outside.

For example, the gate terminal electrode 50 (the source terminal electrode 60) is preferably thicker than the gate electrode 30 (the source electrode 32). The gate terminal electrode 50 (the source terminal electrode 60) is particularly preferably thicker than the chip 2. For example, the gate terminal electrode 50 may cover the region of not more than 25% of the first main surface 3 in plan view. Also, the source terminal electrode 60 may cover the region of not less than 50% of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be ensured, and therefore the discharge phenomenon can be suppressed.

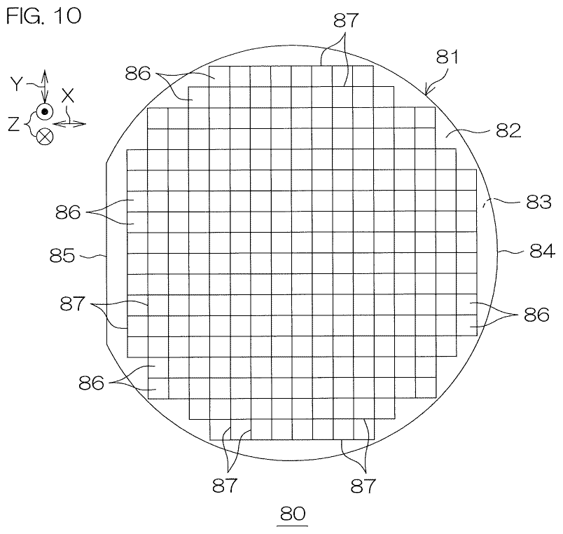

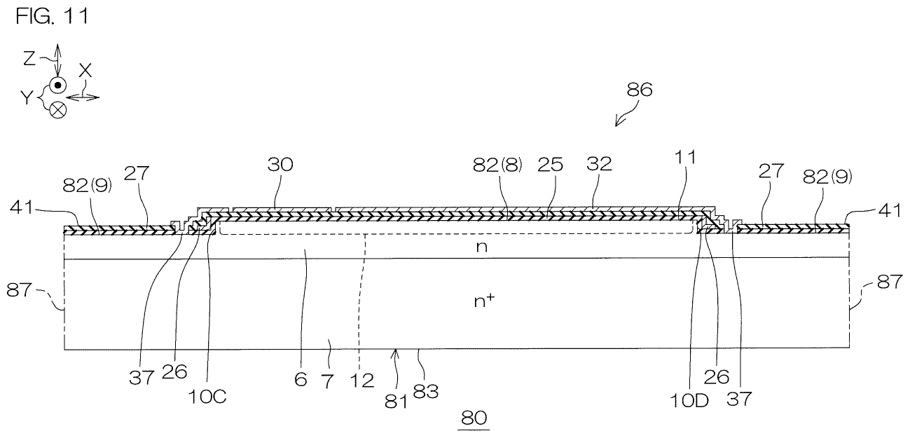

FIG. 10 is a plan view showing a wafer structure 80 that is to be used at a time of manufacturing of the semiconductor device 1A shown in FIG. 1. FIG. 11 is a cross sectional view showing a device region 86 shown in FIG. 10. With reference to FIG. 10 and FIG. 11, the wafer structure 80 includes a wafer 81 formed in a disc shape. The wafer 81 is to be a base of the chip 2. The wafer 81 has a first wafer main surface 82 on one side, a second wafer main surface 83 on the other side, and a wafer side surface 84 connecting the first wafer main surface 82 and the second wafer main surface 83.

The wafer 81 has a mark 85 indicating a crystal orientation of the SiC monocrystal on the wafer side surface 84. The mark 85 includes an orientation flat cut out in a straight line in plan view, in this embodiment. The orientation flat extends in the second direction Y, in this embodiment. The orientation flat does not necessarily have to extend in the second direction Y and may extend in the first direction X.

As a matter of course, the mark 85 may include a first orientation flat extending in the first direction X and a second orientation flat extending in the second direction Y. Also, the mark 85 may have an orientation notch, instead of the orientation flat, cut out toward a central portion of the wafer 81. The orientation notch may be a notched portion cut into a polygonal shape such as a triangle shape and a quadrangle shape in plan view.

The wafer 81 may have a diameter of not less than 50 mm and not more than 300 mm (that is, not less than 2 inch and not more than 12 inch). The diameter of the wafer structure 80 is defined by a length of a chord passing through a center of the wafer structure 80 outside the mark 85. The wafer structure 80 may have a thickness of not less than 100 μm and not more than 1100 μm.

The wafer structure 80 includes the first semiconductor region 6 formed in a region on the first wafer main surface 82 side and the second semiconductor region 7 formed in a region on the second wafer main surface 83 side, inside the wafer 81. The first semiconductor region 6 is formed by an epitaxial layer, and the second semiconductor region 7 formed by a semiconductor substrate. That is, the first semiconductor region 6 is formed by an epitaxial growth of a semiconductor monocrystal from the second semiconductor region 7 by an epitaxial growth method. The second semiconductor region 7 preferably has a thickness exceeding a thickness of the first semiconductor region 6.

The wafer structure 80 includes a plurality of device regions 86 and a plurality of scheduled cutting lines 87 that are provided in the first wafer main surface 82. The plurality of device regions 86 are regions each corresponding to the semiconductor device 1A. The plurality of device regions 86 are each set in a quadrangle shape in plan view. The plurality of device regions 86 are arrayed in a matrix pattern along the first direction X and the second direction Y in plan view, in this embodiment.

The plurality of scheduled cutting lines 87 are lines (regions extending in band shapes) that define positions to be the first to fourth side surfaces 5A to 5D of the chip 2. The plurality of scheduled cutting lines 87 are set in a lattice pattern extending along the first direction X and the second direction Y such as to define the plurality of device regions 86. For example, the plurality of scheduled cutting lines 87 may be demarcated by alignment marks and the like that are provided inside and/or outside the wafer 81.

The wafer structure 80 includes the mesa portion 11, the MISFET structure 12, the outer contact region 19, the outer well region 20, the field regions 21, the main surface insulating film 25, the side wall structure 26, the interlayer insulating film 27, the gate electrode 30, the source electrode 32, the plurality of gate wirings 36A, 36B and the source wiring 37 formed in each of the device regions 86, in this embodiment.

The wafer structure 80 includes the dicing street 41 defined in a region between the source wiring 37 and the field regions 21 (specifically, the outermost field region 21). The dicing street 41 straddles the plurality of device regions 86 across the plurality of scheduled cutting lines 87 such as to expose the plurality of scheduled cutting lines 87. The dicing street 41 is formed in a lattice pattern extending along the plurality of scheduled cutting lines 87. The dicing street 41 exposes the interlayer insulating film 27, in this embodiment.

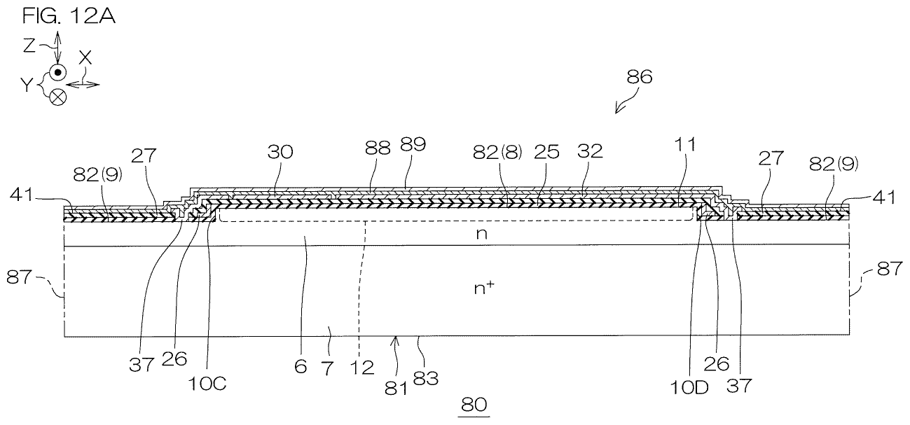

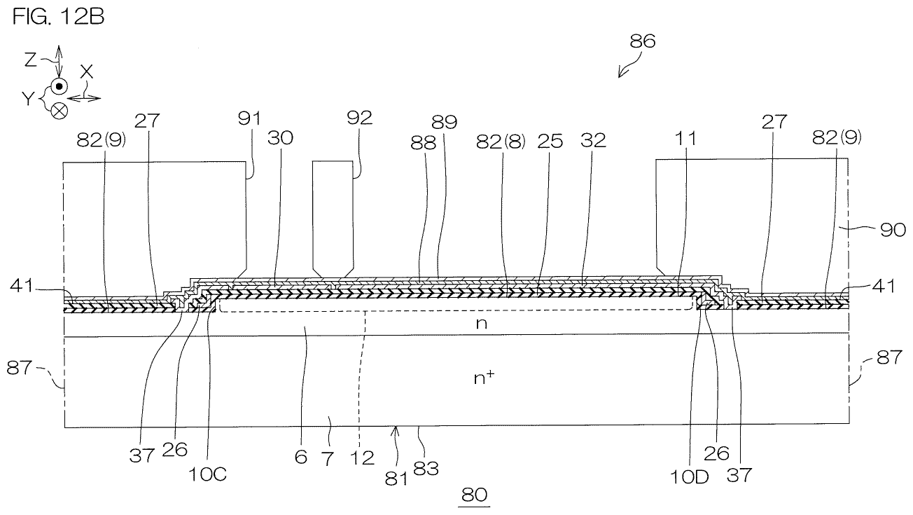

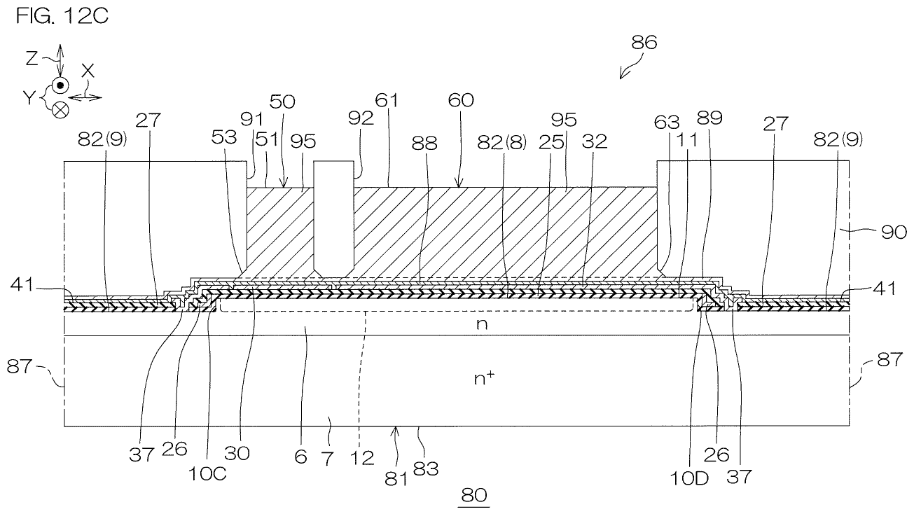

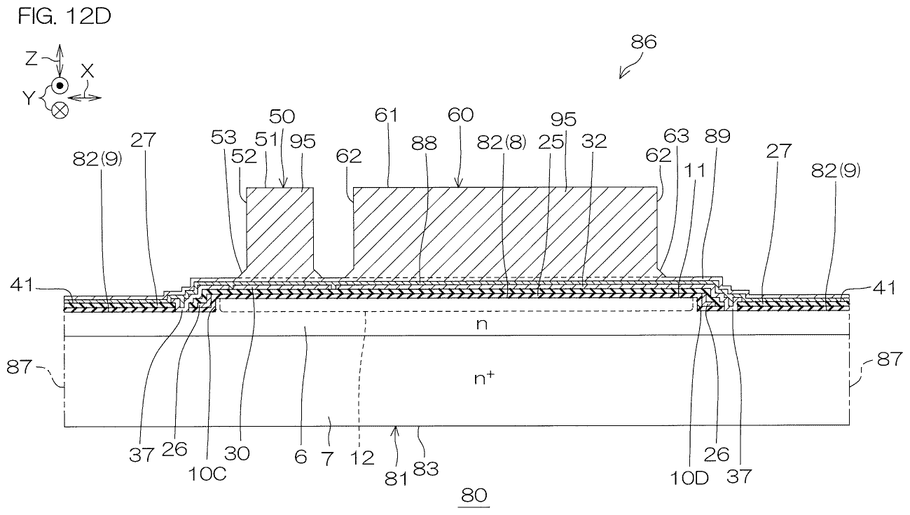

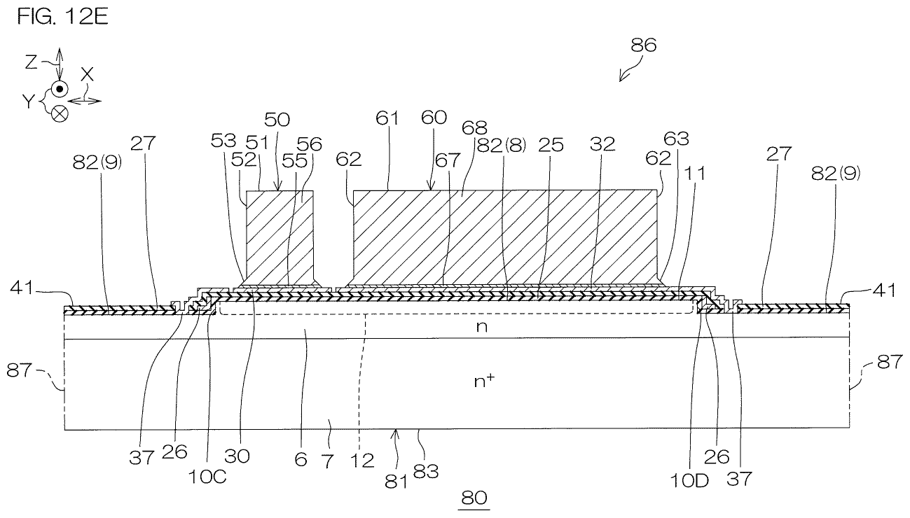

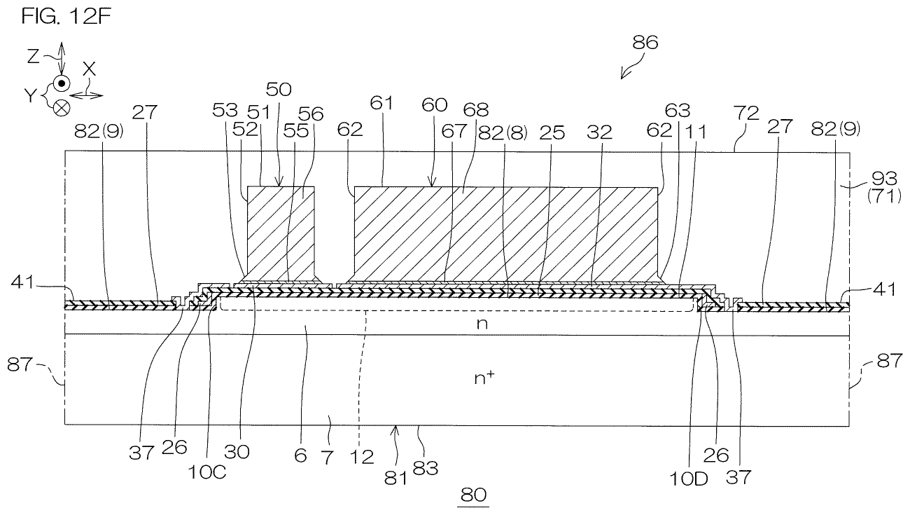

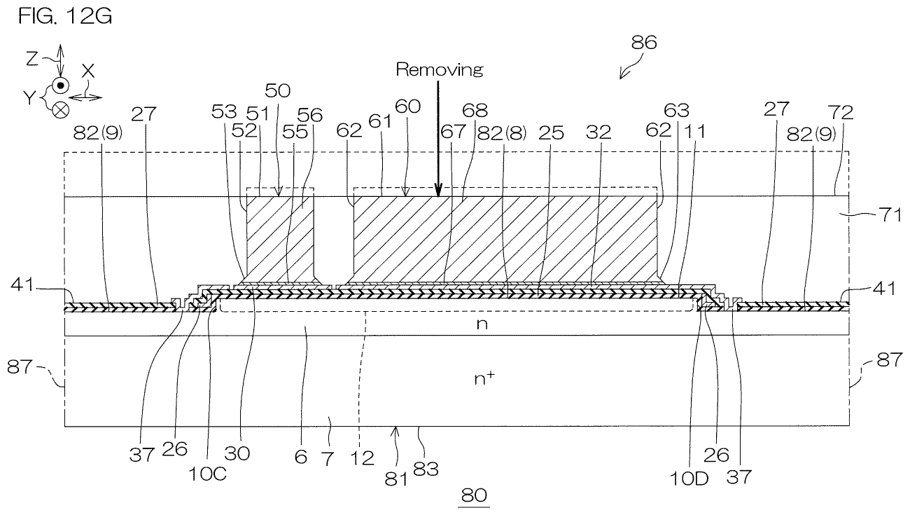

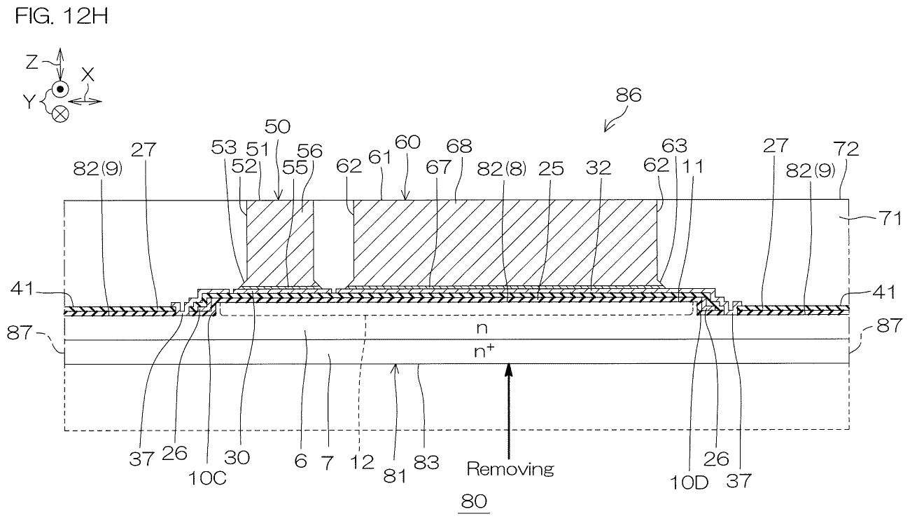

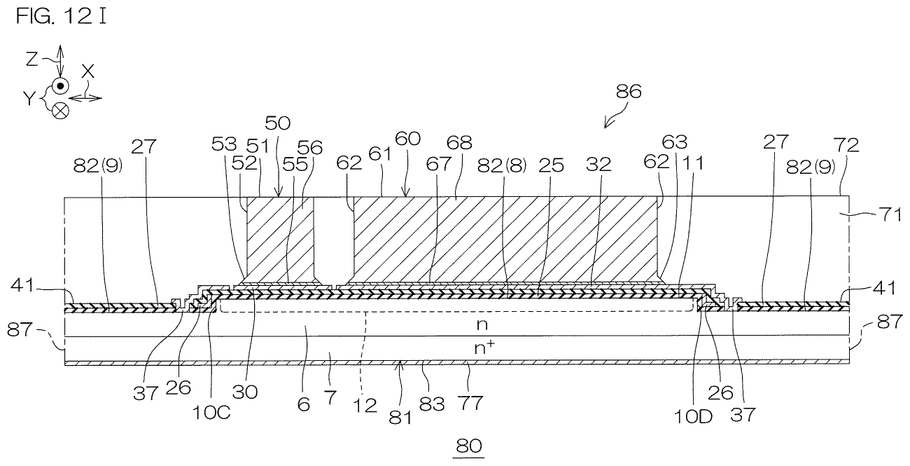

FIG. 12A to FIG. 12I are cross sectional views showing a manufacturing method example for the semiconductor device shown in FIG. 1. Descriptions of the specific features of each structure that are formed in each process shown in FIG. 12A to FIG. 12I shall be omitted or simplified, since those have been as described above.

With reference to FIG. 12A, the wafer structure 80 is prepared (see FIG. 10 and FIG. 11). Next, a first base conductor film 88 to be a base of the first gate conductor film 55 and the first source conductor film 67 is formed on the wafer structure 80. The first base conductor film 88 is formed in a film shape along the interlayer insulating film 27, the gate electrode 30, the source electrode 32, the plurality of gate wirings 36A, 36B, and the source wiring 37. The first base conductor film 88 includes a Ti-based metal film. The first base conductor film 88 may be formed by a sputtering method and/or a vapor deposition method.

Next, a second base conductor film 89 to be a base of the second gate conductor film 56 and the second source conductor film 68 is formed on the first base conductor film 88. The second base conductor film 89 covers the interlayer insulating film 27, the gate electrode 30, the source electrode 32, the plurality of gate wirings 36A, 36B, and the source wiring 37 in a film shape with the first base conductor film 88 interposed therebetween. The second base conductor film 89 includes a Cu-based metal film. The second base conductor film 89 may be formed by a sputtering method and/or a vapor deposition method.

Next, with reference to FIG. 12B, a resist mask 90 having a predetermined pattern is formed on the second base conductor film 89. The resist mask 90 includes a first opening 91 exposing only the gate electrode 30, and a second opening 92 exposing only the source electrode 32. Specifically, the first opening 91 exposes only a portion of the second base conductor film 89 covering the gate electrode 30. Specifically, the second opening 92 exposes only a portion of the second base conductor film 89 covering the source electrode 32. The first opening 91 exposes a region in which the gate terminal electrode 50 is to be formed at a region on the gate electrode 30. The second opening 92 exposes a region in which the source terminal electrode 60 is to be formed at a region on the source electrode 32.

This step includes a step of reducing an adhesion of the resist mask 90 with respect to the second base conductor film 89. The adhesion of the resist mask 90 is to be adjusted by adjusting exposure conditions and/or bake conditions (baking temperature, time, etc.) after exposure for the resist mask 90. Through this step, a growth starting point of the first protrusion portion 53 is formed at a lower end portion of the first opening 91, and a growth starting point of the second protrusion portion 63 is formed at a lower end portion of the second opening 92.

Next, with reference to FIG. 10C, a third base conductor film 95 to be a base of the second gate conductor film 56 and the second source conductor film 68 is formed on the second base conductor film 89. The third base conductor film 95 is formed by depositing a conductor (in this embodiment, Cu-based metal) in the first opening 91 and the second opening 92 by a plating method (for example, electroplating method), in this embodiment. The third base conductor film 95 integrates with the second base conductor film 89 inside the first opening 91 and the second opening 92. Through this step, the gate terminal electrode 50 that covers the gate electrode 30 is formed. Also, the source terminal electrode 60 that covers the source electrode 32 is formed.

This step includes a step of entering a plating solution between the second base conductor film 89 and the resist mask 90 at the lower end portion of the first opening 91. Also, this step includes a step of entering the plating solution between the second base conductor film 89 and the resist mask 90 at the lower end portion of the second opening 92. Through this step, a part of the third base conductor film 95 (the gate terminal electrode 50) is grown into a protrusion shape at the lower end portion of the first opening 91 and the first protrusion portion 53 is thereby formed. Also, a part of the third base conductor film 95 (the source terminal electrode 60) is grown into a protrusion shape at the lower end portion of the second opening 92 and the second protrusion portion 63 is thereby formed.

Next, with reference to FIG. 12D, the resist mask 90 is removed. Through this step, the gate terminal electrode 50 and the source terminal electrode 60 are exposed outside.

Next, with reference to FIG. 12E, a portion of the second base conductor film 89 that is exposed from the gate terminal electrode 50 and the source terminal electrode 60 is removed. An unnecessary portion of the second base conductor film 89 may be removed by an etching method. The etching method may be a wet etching method and/or a dry etching method. Next, a portion of the first base conductor film 88 that is exposed from the gate terminal electrode 50 and the source terminal electrode 60 is removed. An unnecessary portion of the first base conductor film 88 may be removed by an etching method. The etching method may be a wet etching method and/or a dry etching method.

Next, with reference to FIG. 12F, a sealant 93 is supplied on the first wafer main surface 82 such as to cover the gate terminal electrode 50 and the source terminal electrode 60. The sealant 93 is to be a base of the sealing insulator 71. The sealant 93 fills a periphery of the gate terminal electrode 50 and a periphery of the source terminal electrode 60, and covers a whole region of the gate terminal electrode 50 and a whole region of the source terminal electrode 60.

Also, the sealant 93 directly covers a whole region of a part of the gate electrode 30 exposed from the gate terminal electrode 50. Also, the sealant 93 directly covers a whole region of a part of the source electrode 32 exposed from the source terminal electrode 60. The sealant 93 includes the thermosetting resin, the plurality of fillers and the plurality of flexible particles (flexible agent), in this embodiment, and is hardened by heating. Through this step, the sealing insulator 71 is formed. The sealing insulator 71 has the insulating main surface 72 that covers a whole region of the gate terminal electrode 50 and a whole region of the source terminal electrode 60.

Next, with reference to FIG. 12G, the sealing insulator 71 is partially removed. The sealing insulator 71 is ground from the insulating main surface 72 side by a grinding method, in this embodiment. The grinding method may be a mechanical polishing method or a chemical mechanical polishing method. The insulating main surface 72 is ground until the gate terminal electrode 50 and the source terminal electrode 60. This step includes a grinding step of the gate terminal electrode 50 and the source terminal electrode 60. Through this step, the insulating main surface 72 that forms the single grinding surface with the gate terminal electrode 50 (the gate terminal surface 51) and the source terminal electrode 60 (the source terminal surface 61) is formed.

The sealing insulator 71 may be formed in a semi-cured state (incompletely cured state) by adjusting the heating conditions in the step of FIG. 12F aforementioned. In this case, the sealing insulator 71 is ground in the step of FIG. 12G and then heated again to form a fully cured state (completely cured state). In this case, it is possible to easily remove the sealing insulator 71.

Next, with reference to FIG. 12H, the wafer 81 is partially removed from the second wafer main surface 83 side, and the wafer 81 is thinned until a desired thickness is obtained. The thinning step of the wafer 81 is performed by an etching method or a grinding method. The etching method may be a wet etching method or a dry etching method. The grinding method may be a mechanical polishing method or a chemical mechanical polishing method.

This step includes a step of thinning the wafer 81 by using the sealing insulator 71 as a supporting member that supports the wafer 81. This allows for proper handling of the wafer 81. Also, it is possible to suppress a deformation (warpage due to thinning) of the wafer 81 with the sealing insulator 71, and therefore the wafer 81 can be appropriately thinned.

As one example, in a case in which the thickness of the wafer 81 is less than the thickness of the sealing insulator 71, the wafer 81 is further thinned. As the other example, in a case in which the thickness of the wafer 81 is not less than the thickness of the sealing insulator 71, the wafer 81 is thinned until the thickness of the wafer 81 becomes less than the thickness of the sealing insulator 71. In those cases, the wafer 81 is preferably thinned until a thickness of the second semiconductor region 7 (the semiconductor substrate) becomes less than a thickness of the first semiconductor region 6 (the epitaxial layer).

As a matter of course, the thickness of the second semiconductor region 7 (the semiconductor substrate) may be not less than the thickness of the first semiconductor region 6 (the epitaxial layer). Also, the wafer 81 may be thinned until the first semiconductor region 6 is exposed from the second wafer main surface 83. That is, all of the second semiconductor region 7 may be removed.

Next, with reference to FIG. 12I, the drain electrode 77 covering the second wafer main surface 83 is formed. The drain electrode 77 may be formed by a sputtering method and/or a vapor deposition method. Next, the wafer structure 80 and the sealing insulator 71 cut along the scheduled cutting lines 87. The wafer structure 80 and the sealing insulator 71 may be cut by a dicing blade (not shown). Through the steps including the above, the plurality of semiconductor devices 1A are manufactured from the single wafer structure 80.

As described above, the manufacturing method for the semiconductor device 1A includes the step of preparing the wafer structure 80, the step of forming the gate terminal electrode 50, and the step of forming the sealing insulator 71. In the step of preparing the wafer structure 80, the wafer structure 80 that includes the wafer 81 and the gate electrode 30 (the main surface electrode) is prepared. The wafer 81 has the first wafer main surface 82. The gate electrode 30 is arranged on the first wafer main surface 82.

In the step of forming the gate terminal electrode 50, the gate terminal electrode 50 is formed on the gate electrode 30 such as to expose a part of the gate electrode 30. In the step of forming the sealing insulator 71, the sealing insulator 71 is formed that covers the periphery of the gate terminal electrode 50 such as to expose a part of the gate terminal electrode 50, and that has the portion directly covering the gate electrode 30.

In accordance with the manufacturing method above, since no other member is interposed between the gate electrode 30 and the sealing insulator 71, the starting points for peel-off between the gate electrode 30 and the sealing insulator 71 can be reduced. This allows the sealing insulator 71 to adequately protect a sealing target (e.g. the gate electrode 30). That is, it is possible to protect the sealing target from damage due to an external force and/or degradation due to moisture. This allows for shape defects and variations in the electrical properties to be suppressed. It is therefore possible to manufacture the semiconductor device 1A capable of improving reliability.

From another point of view, the manufacturing method for the semiconductor device 1A includes the step of preparing the wafer structure 80, the step of forming the source terminal electrode 60, and the step of forming the sealing insulator 71. In the step of preparing the wafer structure 80, the wafer structure 80 that includes the wafer 81 and the source electrode 32 (the main surface electrode) is prepared. The wafer 81 has the first wafer main surface 82. The source electrode 32 is arranged on the first wafer main surface 82.

In the step of forming the source terminal electrode 60, the source terminal electrode 60 is formed on the source electrode 32 such as to expose a part of the source electrode 32. In the step of forming the sealing insulator 71, the sealing insulator 71 is formed that covers the periphery of the source terminal electrode 60 such as to expose a part of the source terminal electrode 60, and that has the portion directly covering the source electrode 32.

In accordance with the manufacturing method above, since no other member is interposed between the source electrode 32 and the sealing insulator 71, the starting points for peel-off between the source electrode 32 and the sealing insulator 71 can be reduced. This allows the sealing insulator 71 to adequately protect a sealing target (e.g. the source electrode 32). That is, it is possible to protect the sealing target from damage due to an external force and/or degradation due to moisture. This allows for shape defects and variations in the electrical properties to be suppressed. It is therefore possible to manufacture the semiconductor device 1A capable of improving reliability.

In the step of forming the gate terminal electrode 50 (a source terminal electrode 60), the gate terminal electrode 50 (the source terminal electrode 60) is preferably formed that exposes at least a part of the corner portion of the gate electrode 30 (the source electrode 32). In this case, in the step of forming the sealing insulator 71, the sealing insulator 71 is preferably formed that directly covers at least a part of the corner portion of the gate electrode 30 (the source electrode 32).

That is, in the step of forming the gate terminal electrode 50 (a source terminal electrode 60), the gate terminal electrode 50 (the source terminal electrode 60) is preferably formed that exposes the gate electrode surface 30a (the source electrode surface 32a) and the gate electrode side wall 30b (the source electrode side wall 32b). Also, in the step of forming the sealing insulator 71, the sealing insulator 71 is preferably formed that directly covers the gate electrode surface 30a (the source electrode surface 32a) and the gate electrode side wall 30b (the source electrode side wall 32b).

In accordance with the manufacturing methods above, it is possible to reduce the peel-off starting points at the corner portion of the gate electrode 30 (the source electrode 32). This also allows the sealing insulator 71 to protect the corner portion of the gate electrode 30 (the source electrode 32). Accordingly, it is possible to suppress ingress of moisture or the like starting at the corner portion of the gate electrode 30 (the source electrode 32). This can make the gate electrode 30 (the source electrode 32) and/or the gate terminal electrode 50 (the source terminal electrode 60) less likely to degrade due to moisture or the like for improved reliability.

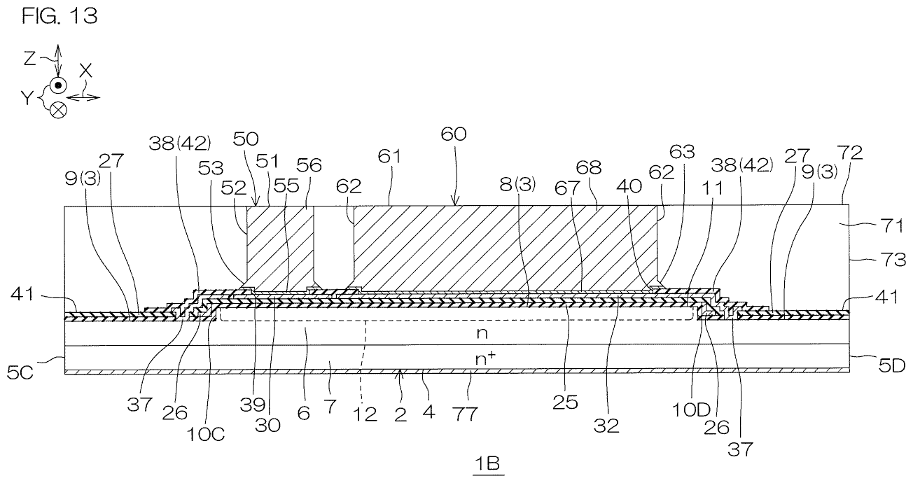

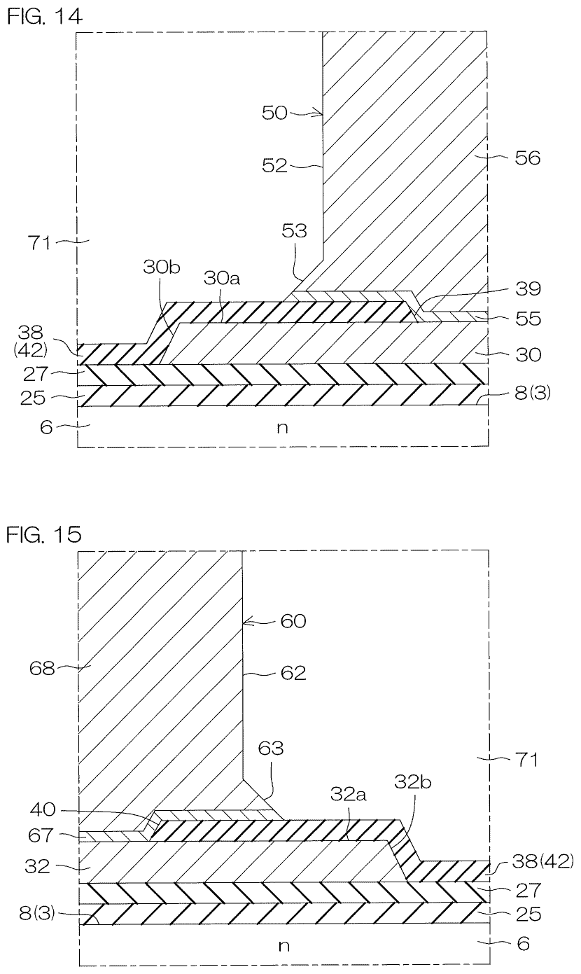

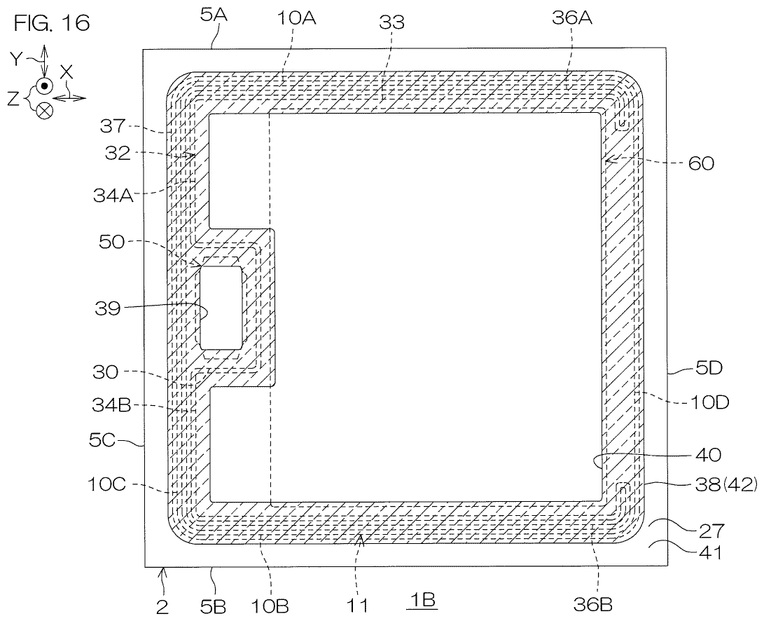

FIG. 13 is a cross sectional view showing a semiconductor device 1B according to a second embodiment. FIG. 14 is a cross sectional view showing a main part of the gate terminal electrode 50 shown in FIG. 13. FIG. 15 is a cross sectional view showing a main part of the source terminal electrode 60 shown in FIG. 13. FIG. 16 is a plan view showing a layout example of an upper insulating film 38 shown in FIG. 13. With reference to FIG. 13 to FIG. 16, the semiconductor device 1B has a modified mode of the semiconductor device 1A. The semiconductor device 1B includes the upper insulating film 38 that directly covers the gate electrode 30, the source electrode 32, the plurality of gate wirings 36A, 36B and the source wiring 37.

The upper insulating film 38 has a gate opening 39 that exposes an inner portion of the gate electrode 30, and has a portion that directly covers at least a part of the corner portion (peripheral edge portion) of the gate electrode 30. The upper insulating film 38 directly covers the whole region of the corner portion of the gate electrode 30, in this embodiment. The upper insulating film 38 directly covers the gate electrode surface 30a and the gate electrode side wall 30b at the corner portion of the gate electrode 30. A portion of the upper insulating film 38 that directly covers the gate electrode side wall 30b is in contact with the interlayer insulating film 27. The gate opening 39 is formed in a quadrilateral shape along the peripheral edge of the gate electrode 30 in plan view, in this embodiment.

The upper insulating film 38 has a source opening 40 that exposes an inner portion of the source electrode 32, and has a portion that directly covers at least a part of the corner portion (peripheral edge portion) of the source electrode 32. The upper insulating film 38 directly covers the whole region of the corner portion of the source electrode 32, in this embodiment. The upper insulating film 38 directly covers the source electrode surface 32a and the source electrode side wall 32b at the corner portion of the source electrode 32. A portion of the upper insulating film 38 that directly covers the source electrode side wall 32b is in contact with the interlayer insulating film 27. The source opening 40 is formed in a polygonal shape along the peripheral edge of the source electrode 32 in plan view, in this embodiment.

The upper insulating film 38 directly covers the whole region of the plurality of gate wirings 36A, 36B and the whole region of the source wiring 37, in this embodiment. The upper insulating film 38 covers the side wall structure 26 with the interlayer insulating film 27 interposed therebetween and is drawn out from the active surface 8 side to the outer surface 9 side. The upper insulating film 38 is formed at an interval inward from the peripheral edge (the first to fourth side surfaces 5A to 5D) of the outer surface 9 and covers the outer contact region 19, the outer well region 20, and the plurality of field regions 21. The upper insulating film 38 defines the dicing street 41 between the upper insulating film 38 and each peripheral edge of the outer surface 9.

The dicing street 41 is formed in a band shape that extends along the peripheral edge (the first to fourth side surfaces 5A to 5D) of the outer surface 9 in plan view. The dicing street 41 is formed in an annular shape (specifically, quadrilateral annular shape) that surrounds the inner portion (active surface 8) of the first main surface 3 in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The upper insulating film 38 may also be formed that extends to the peripheral edge of the first main surface 3 such as to be continuous with the first to fourth side surfaces 5A to 5D. In this case, the dicing street 41 is set in a region between the peripheral edge of the first main surface 3 and the source wiring 37 (specifically, the outermost field region 21) as with the case of the first embodiment.

The dicing street 41 may have a width of not less than 1 μm and not more than 200 μm. The width of the dicing street 41 is a width in a direction orthogonal to the direction in which the dicing street 41 extends. The width of the dicing street 41 is preferably not less than 5 μm and not more than 50 μm. The upper insulating film 38 may have a thickness less than the thickness of the gate electrode 30 (the source electrode 32). The upper insulating film 38 may have a thickness that exceeds the thickness of the gate electrode 30 (the source electrode 32). The thickness of the upper insulating film 38 is preferably less than the thickness of the chip 2.

The upper insulating film 38 has a single layered structure comprising an inorganic insulating film 42 (inorganic film). The inorganic insulating film 42 may include at least one of a silicon oxide film (oxide film), a silicon nitride film (nitride film) and a silicon oxynitride film (oxynitride film). The inorganic insulating film 42 preferably includes an insulator different from one of or both asf that of the main surface insulating film 25 and that of the interlayer insulating film 27. The inorganic insulating film 42 comprises the silicon nitride film, in this embodiment.

The inorganic insulating film 42 preferably has a thickness less than the thickness of the gate electrode 30 and the thickness of the source electrode 32. The inorganic insulating film 42 preferably has the thickness less than the thickness of the interlayer insulating film 27. The thickness of the inorganic insulating film 42 may be not less than 0.1 μm and not more than 5 μm.

The gate terminal electrode 50 has an area less than the area of the gate electrode 30 in plan view, and is arranged on the inner portion of the gate electrode 30 at an interval from the peripheral edge of the gate electrode 30 as with the case of the first embodiment. The gate terminal electrode 50 has a thickness that exceeds the thickness of the upper insulating film 38, in this embodiment. The gate terminal electrode 50 extends from on the gate electrode 30 onto the upper insulating film 38 and directly covers the gate electrode 30 and the upper insulating film 38. The gate terminal electrode 50 exposes a portion in the upper insulating film 38 that covers the corner portion (i.e. the gate electrode surface 30a and the gate electrode side wall 30b) of the gate electrode 30, in this embodiment.

The gate terminal side wall 52 of the gate terminal electrode 50 is positioned on the upper insulating film 38 and extends substantially vertically in the normal direction Z. The gate terminal side wall 52 faces the gate electrode 30 with the upper insulating film 38 interposed therebetween. The first protrusion portion 53 of the gate terminal electrode 50 extends along the outer surface of the upper insulating film 38, and is formed in a tapered shape in which the thickness gradually decreases from the gate terminal side wall 52 toward the tip portion in cross sectional view, in this embodiment.

The gate terminal electrode 50 has a laminated structure that includes the first gate conductor film 55 and the second gate conductor film 56 as with the case of the first embodiment. The first gate conductor film 55 covers the gate electrode 30 in a film shape within the gate opening 39, and is drawn out in a film shape on the upper insulating film 38, in this embodiment. The second gate conductor film 56 covers the gate electrode 30 with the first gate conductor film 55 interposed therebetween within the gate opening 39, and is drawn out in a film shape on the upper insulating film 38 with the first gate conductor film 55 interposed therebetween, in this embodiment.

The source terminal electrode 60 has an area less than the area of the source electrode 32 in plan view, and is arranged on the inner portion of the source electrode 32 at an interval from the peripheral edge of the source electrode 32 as with the case of the first embodiment. The source terminal electrode 60 has a thickness that exceeds the thickness of the upper insulating film 38, in this embodiment. The source terminal electrode 60 extends from on the source electrode 32 onto the upper insulating film 38 and directly covers the source electrode 32 and the upper insulating film 38. The source terminal electrode 60 exposes a portion in the upper insulating film 38 that covers the corner portion (i.e. the source electrode surface 32a and the source electrode side wall 32b) of the source electrode 32, in this embodiment.

The source terminal side wall 62 of the source terminal electrode 60 is positioned on the upper insulating film 38 and extends substantially vertically in the normal direction Z, in this embodiment. The source terminal side wall 62 faces the source electrode 32 with the upper insulating film 38 interposed therebetween. The second protrusion portion 63 of the source terminal electrode 60 extends along the outer surface of the upper insulating film 38, and is formed in a tapered shape in which the thickness gradually decreases from the source terminal side wall 62 toward the tip portion in cross sectional view, in this embodiment.

The source terminal electrode 60 has a laminated structure that includes the first source conductor film 67 and the second source conductor film 68 as with the case of the first embodiment. The first source conductor film 67 covers the source electrode 32 in a film shape within the source opening 40, and is drawn out in a film shape on the upper insulating film 38, in this embodiment. The second source conductor film 68 covers the source electrode 32 with the first source conductor film 67 interposed therebetween within the source opening 40, and is drawn out in a film shape on the upper insulating film 38 with the first source conductor film 67 interposed therebetween, in this embodiment.

The sealing insulator 71 has a portion that directly covers the upper insulating film 38, in this embodiment. With reference to FIG. 14, the sealing insulator 71 has a portion that directly covers the upper insulating film 38 on the gate electrode 30. That is, the sealing insulator 71 has a portion that covers the gate electrode 30 with the upper insulating film 38 interposed therebetween. Specifically, the sealing insulator 71 has a portion that covers at least a part of the corner portion of the gate electrode 30 with the upper insulating film 38 interposed therebetween.

The sealing insulator 71 covers the whole region of the corner portion of the gate electrode 30 with the upper insulating film 38 interposed therebetween, in this embodiment. The sealing insulator 71 covers the gate electrode surface 30a and the gate electrode side wall 30b at the corner portion of the gate electrode 30 with the upper insulating film 38 interposed therebetween. The sealing insulator 71 is formed on the upper insulating film 38 at an interval from the gate opening 39 toward the corner portion of the gate electrode 30, in this embodiment.

That is, the sealing insulator 71 has a portion in contact only with the upper insulating film 38 and the gate terminal electrode 50 (the gate terminal side wall 52) immediately above the gate electrode 30, and does not have a portion that directly covers the gate electrode 30, in this embodiment. The sealing insulator 71 covers the first protrusion portion 53 on a lower end portion side of the gate terminal electrode 50, and has a portion that faces the upper insulating film 38 with the first protrusion portion 53 interposed therebetween, in this embodiment.

With reference to FIG. 15, the sealing insulator 71 has a portion that directly covers the upper insulating film 38 on the source electrode 32. That is, the sealing insulator 71 has a portion that covers the source electrode 32 with the upper insulating film 38 interposed therebetween. Specifically, the sealing insulator 71 has a portion that covers at least a part of the corner portion of the source electrode 32 with the upper insulating film 38 interposed therebetween.

The sealing insulator 71 covers the whole region of the corner portion of the source electrode 32 with the upper insulating film 38 interposed therebetween, in this embodiment. The sealing insulator 71 covers the source electrode surface 32a and the source electrode side wall 32b at the corner portion of the source electrode 32 with the upper insulating film 38 interposed therebetween. The sealing insulator 71 is formed on the upper insulating film 38 at an interval from the source opening 40 toward the corner portion of the source electrode 32, in this embodiment.

That is, the sealing insulator 71 has a portion in contact only with the upper insulating film 38 and the source terminal electrode 60 (the source terminal side wall 62) immediately above the source electrode 32, and does not have a portion that directly covers the source electrode 32, in this embodiment. The sealing insulator 71 covers the second protrusion portion 63 on a lower end portion side of the source terminal electrode 60, and has a portion that faces the upper insulating film 38 with the second protrusion portion 63 interposed therebetween, in this embodiment.

The sealing insulator 71 covers the whole region of the plurality of gate wirings 36A, 36B and the whole region of the source wiring 37 with the upper insulating film 38 interposed therebetween, in this embodiment. The sealing insulator 71 may include a plurality of fillers with a thickness that exceeds the thickness of the upper insulating film 38.

As described above, the semiconductor device 1B includes the chip 2, the gate electrode 30 (the main surface electrode), the gate terminal electrode 50, the upper insulating film 38 (the insulating film), and the sealing insulator 71. The chip 2 has the first main surface 3. The gate electrode 30 is arranged on the first main surface 3. The upper insulating film 38 has the single layered structure comprising the inorganic insulating film 42 (the inorganic film) and directly covers the gate electrode 30 such as to expose a part of the gate electrode 30. The gate terminal electrode 50 is arranged on the gate electrode 30. The sealing insulator 71 covers a periphery of the gate terminal electrode 50 such as to expose a part of the gate terminal electrode 50, and has the portion that directly covers the upper insulating film 38.

In accordance with the structure above, the upper insulating film 38 allows the gate electrode 30 to be protected from an external force and/or moisture. Also, in accordance with the structure above, since no laminated film is interposed between the gate electrode 30 and the sealing insulator 71, the starting points for peel-off between the gate electrode 30 and the sealing insulator 71 can be reduced.

This allows both the upper insulating film 38 and the sealing insulator 71 to adequately protect a sealing target (e.g. the gate electrode 30). That is, it is possible to protect the sealing target (e.g. the gate electrode 30) from damage due to an external force and/or degradation due to moisture. This allows for shape defects and variations in the electrical properties to be suppressed. It is therefore possible to provide the semiconductor device 1B capable of improving reliability.

From another point of view, the semiconductor device 1B includes the chip 2, the source electrode 32 (the main surface electrode), the source terminal electrode 60, the upper insulating film 38 (the insulating film), and the sealing insulator 71. The chip 2 has the first main surface 3. The source electrode 32 is arranged on the first main surface 3. The upper insulating film 38 has the single layered structure comprising the inorganic insulating film 42 (the inorganic film) and directly covers the source electrode 32 such as to expose a part of the source electrode 32. The source terminal electrode 60 is arranged on the source electrode 32. The sealing insulator 71 covers a periphery of the source terminal electrode 60 such as to expose a part of the source terminal electrode 60, and has the portion that directly covers the upper insulating film 38 on the source electrode 32.

In accordance with the structure above, the upper insulating film 38 allows the source electrode 32 to be protected from an external force and/or moisture. Also, in accordance with the structure above, since no laminated film is interposed between the source electrode 32 and the sealing insulator 71, the starting points for peel-off between the source electrode 32 and the sealing insulator 71 can be reduced.

This allows both the upper insulating film 38 and the sealing insulator 71 to adequately protect a sealing target (e.g. the source electrode 32). That is, it is possible to protect the sealing target (e.g. the source electrode 32) from damage due to an external force and/or degradation due to moisture. This allows for shape defects and variations in the electrical properties to be suppressed. It is therefore possible to provide the semiconductor device 1B capable of improving reliability.

It is preferable that the upper insulating film 38 directly covers at least a part of the corner portion of the gate electrode 30 (the source electrode 32). That is, it is preferable that the upper insulating film 38 directly covers the gate electrode surface 30a (the source electrode surface 32a) and the gate electrode side wall 30b (the source electrode side wall 32b). In accordance with the structure above, it is possible to reduce the peel-off starting points at the corner portion of the gate electrode 30 (the source electrode 32), and to adequately suppress ingress of moisture or the like starting at the corner portion of the gate electrode 30 (the source electrode 32).

In this case, the sealing insulator 71 preferably covers at least a part of the corner portion of the gate electrode 30 (the source electrode 32) with the upper insulating film 38 interposed therebetween. That is, the sealing insulator 71 preferably has the portion that covers the gate electrode surface 30a (the source electrode surface 32a) and the gate electrode side wall 30b (the source electrode side wall 32b) with the upper insulating film 38 interposed therebetween.

In accordance with the structure above, both the upper insulating film 38 and the sealing insulator 71 allow the corner portion of the gate electrode 30 (the source electrode 32) to be protected adequately. The gate terminal electrode 50 (the source terminal electrode 60) preferably has a portion that is positioned on the gate electrode 30 (the source electrode 32) and a portion that is positioned on the upper insulating film 38.

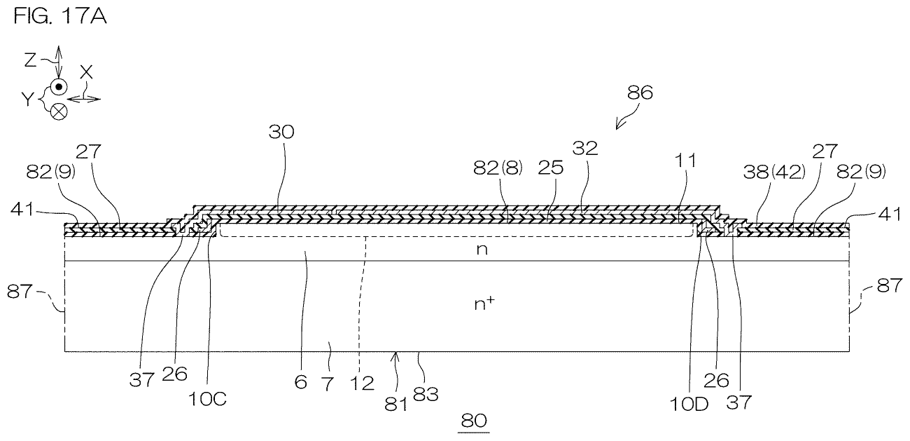

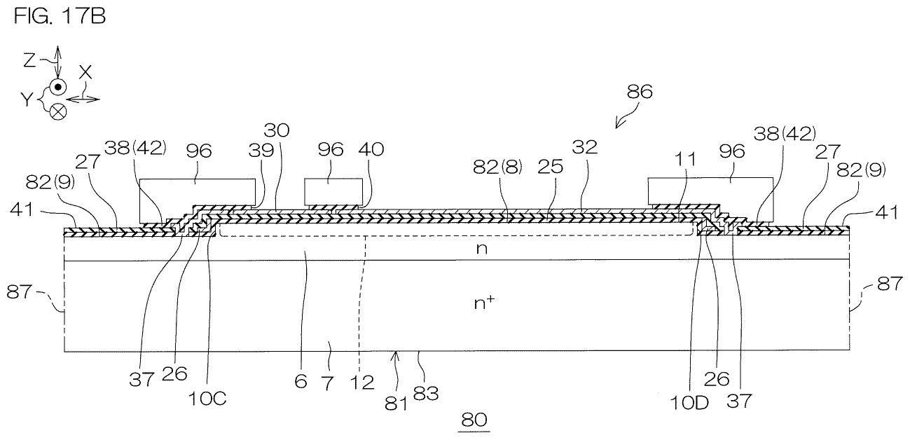

FIGS. 17A and 17B are cross sectional views showing a manufacturing method example for the semiconductor device 1B shown in FIG. 13. FIGS. 17A and 17B show the step of forming the upper insulating film 38 (inorganic insulating film 42). The step of forming the upper insulating film 38 (see FIGS. 17A and 17B) is performed prior to the aforementioned step of forming the gate terminal electrode 50 and the source terminal electrode 60 (see FIGS. 12A to 12I).

With reference to FIG. 17A, the wafer structure 80 is prepared (see FIGS. 10 and 11). Next, the upper insulating film 38 is formed on the first wafer main surface 82. The upper insulating film 38 directly covers the interlayer insulating film 27, the gate electrode 30, the source electrode 32, the plurality of gate wirings 36A, 36B, and the source wiring 37. The upper insulating film 38 has the single layered structure comprising the inorganic insulating film 42, in this embodiment. The upper insulating film 38 may be formed by a CVD (Chemical Vapor Deposition) method.

Next, with reference to FIG. 17B, a resist mask 96 that has a predetermined pattern is formed on the upper insulating film 38. The resist mask 96 exposes regions in which the gate opening 39, the source opening 40, and the dicing street 41 are to be formed in the upper insulating film 38, and covers the other regions.

Next, an unnecessary portion of the upper insulating film 38 is removed via the resist mask 96 by an etching method. The etching method may be a wet etching method and/or a dry etching method. Through this step, the upper insulating film 38 that defines the gate opening 39, the source opening 40, and the dicing street 41 is formed. Thereafter, the resist mask 96 is removed. The steps shown in FIGS. 12A to 12I are then performed sequentially and the semiconductor device 1B is manufactured.

As described above, the manufacturing method for the semiconductor device 1B includes the step of preparing the wafer structure 80, the step of forming the upper insulating film 38, the step of forming the gate terminal electrode 50, and the step of forming the sealing insulator 71. In the step of preparing the wafer structure 80, the wafer structure 80 that includes the wafer 81 and the gate electrode 30 (a main surface electrode) is prepared. The wafer 81 has the first wafer main surface 82. The gate electrode 30 is arranged on the first wafer main surface 82.

In the step of forming the upper insulating film 38, the upper insulating film 38 is formed that directly covers the gate electrode 30 such as to expose a part of the gate electrode 30. In the step of forming the gate terminal electrode 50, the gate terminal electrode 50 is formed on the gate electrode 30. In the step of forming the sealing insulator 71, the sealing insulator 71 is formed that covers the periphery of the gate terminal electrode 50 such as to expose a part of the gate terminal electrode 50, and that has the portion directly covering the upper insulating film 38.

In accordance with the manufacturing method above, the upper insulating film 38 allows the gate electrode 30 to be protected from an external force and/or moisture. Also, in accordance with the manufacturing method above, since no laminated film is interposed between the gate electrode 30 and the sealing insulator 71, the starting points for peel-off between the gate electrode 30 and the sealing insulator 71 can be reduced.

This allows both the upper insulating film 38 and the sealing insulator 71 to adequately protect a sealing target (e.g. the gate electrode 30). That is, it is possible to protect the sealing target (e.g. the gate electrode) from damage due to an external force and/or degradation due to moisture. This allows for shape defects and variations in the electrical properties to be suppressed. It is therefore possible to manufacture the semiconductor device 1B capable of improving reliability.

From another point of view, the manufacturing method for the semiconductor device 1B includes the step of preparing the wafer structure 80, the step of forming the upper insulating film 38, the step of forming the source terminal electrode 60, and the step of forming the sealing insulator 71. In the step of preparing the wafer structure 80, the wafer structure 80 that includes the wafer 81 and the source electrode 32 (a main surface electrode) is prepared. The wafer 81 has the first wafer main surface 82. The source electrode 32 is arranged on the first wafer main surface 82.

In the step of forming the upper insulating film 38, the upper insulating film 38 is formed that directly covers the source electrode 32 such as to expose a part of the source electrode 32. In the step of forming the source terminal electrode 60, the source terminal electrode 60 is formed on the source electrode 32. In the step of forming the sealing insulator 71, the sealing insulator 71 is formed that covers a periphery of the source terminal electrode 60 such as to expose a part of the source terminal electrode 60, and that has the portion directly covering the upper insulating film 38 on the source electrode 32.

In accordance with the manufacturing method above, the upper insulating film 38 allows the source electrode 32 to be protected from an external force and/or moisture. Also, in accordance with the manufacturing method above, since no laminated film is interposed between the source electrode 32 and the sealing insulator 71, the starting points for peel-off between the source electrode 32 and the sealing insulator 71 can be reduced.

This allows both the upper insulating film 38 and the sealing insulator 71 to adequately protect a sealing target (e.g. the source electrode 32). That is, it is possible to protect the sealing target (e.g. the source electrode 32) from damage due to an external force and/or degradation due to moisture. This allows for shape defects and variations in the electrical properties to be suppressed. It is therefore possible to manufacture the semiconductor device 1B capable of improving reliability.

In the step of forming the upper insulating film 38, the upper insulating film 38 is preferably formed that directly covers at least a part of the corner portion of the gate electrode 30 (the source electrode 32). In this case, in the step of forming the sealing insulator 71, the sealing insulator 71 is preferably formed that covers at least a part of the corner portion of the gate electrode 30 (the source electrode 32) with the upper insulating film 38 interposed therebetween.

That is, in the step of forming the upper insulating film 38, the upper insulating film 38 is preferably formed that directly covers the gate electrode surface 30a (the source electrode surface 32a) and the gate electrode side wall 30b (the source electrode side wall 32b). In this case, in the step of forming the sealing insulator 71, the sealing insulator 71 is preferably formed that covers the gate electrode surface 30a (the source electrode surface 32a) and the gate electrode side wall 30b (the source electrode side wall 32b) with the upper insulating film 38 interposed therebetween. In accordance with the manufacturing methods above, the upper insulating film 38 and the sealing insulator 71 allows the corner portion of the gate electrode 30 (the source electrode 32) to be protected.

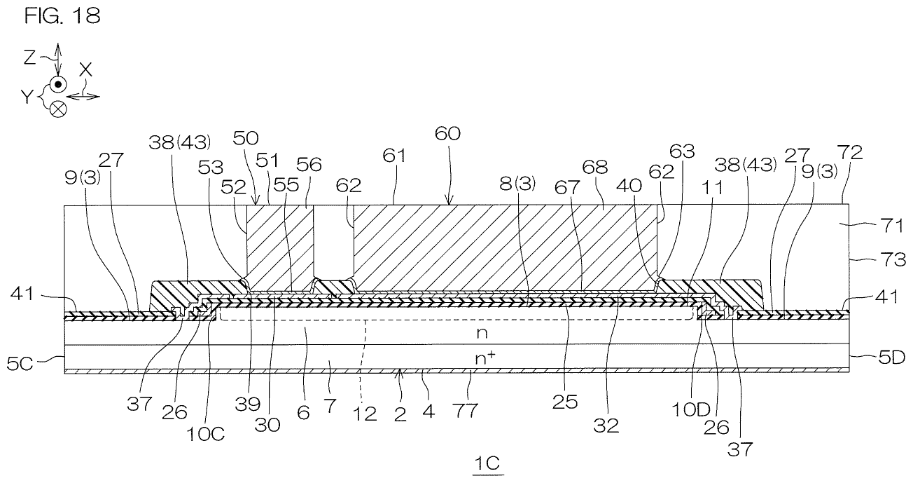

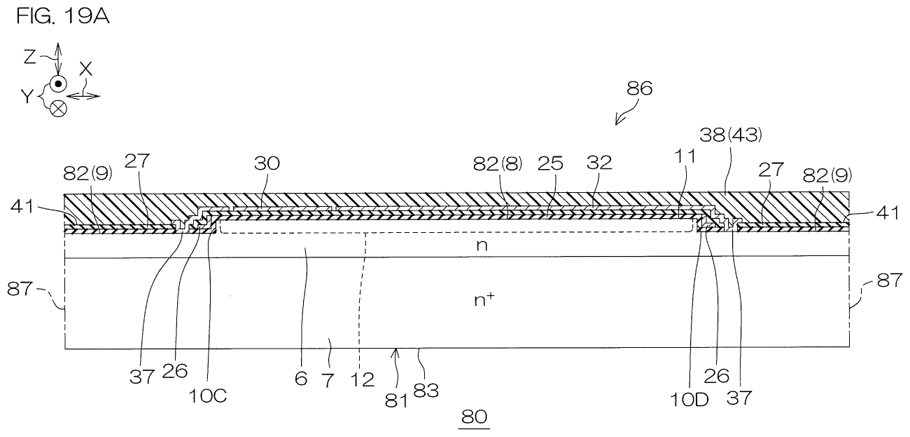

FIG. 18 is a cross sectional view showing a semiconductor device 1C according to a third embodiment. With reference to FIG. 18, the semiconductor device 1C has a modified mode of the semiconductor device 1B (see FIG. 13). Specifically, the semiconductor device 1C includes the upper insulating film 38 that has a single layered structure comprising an inorganic insulating film 43 (inorganic film) instead of the organic insulating film 42, and that directly covers the gate electrode 30, the source electrode 32, the plurality of gate wirings 36A, 36B and the source wiring 37.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The other configuration of the upper insulating film 38 is similar to that of the semiconductor device 1B and therefore the description thereof will be omitted. The gate terminal electrode 50, the source terminal electrode 60, and the sealing insulator 71 are also formed in a similar manner to the case of the semiconductor device 1B and therefore the description thereof will be omitted. As described above, the same effects as those of the semiconductor device 1B are also achieved with the semiconductor device 1C.

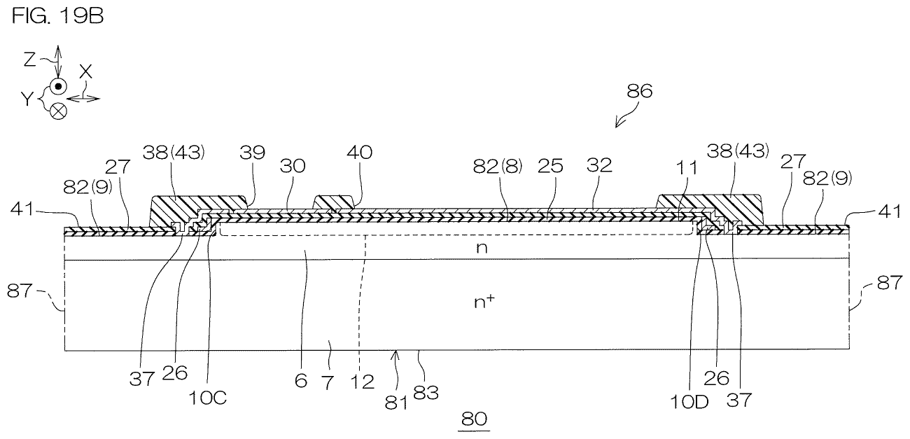

FIGS. 19A and 19B are cross sectional views showing a manufacturing method example for the semiconductor device 1C shown in FIG. 18. FIGS. 19A and 19B show the step of forming the upper insulating film 38 (organic insulating film 43). The step of forming the upper insulating film 38 (see FIGS. 19A and 19B) is performed prior to the aforementioned step of forming the gate terminal electrode 50 and the source terminal electrode 60 (see FIGS. 12A to 12I).

With reference to FIG. 19A, a fluidic resin to be a base of the organic insulating film 43 is applied onto the first wafer main surface 82. The resin is composed of photosensitive resin, in this embodiment. For example, the photosensitive resin is applied to a central portion of the first wafer main surface 82, and spread in a liquid film form to the peripheral edge portion of the first wafer main surface 82 by a spin coating method.

Next, with reference to FIG. 19B, the photosensitive resin in the liquid film form is exposed with patterns that correspond to the gate opening 39, the source opening 40, and the dicing street 41 and then developed. Through this step, the upper insulating film 38 defining the gate opening 39, the source opening 40, and the dicing street 41 is formed. The steps shown in FIGS. 12A to 12I are then performed sequentially and the semiconductor device 1C is manufactured. As described above, the same effects as those of the manufacturing method for the semiconductor device 1B are also achieved with the manufacturing method for the semiconductor device 1C.

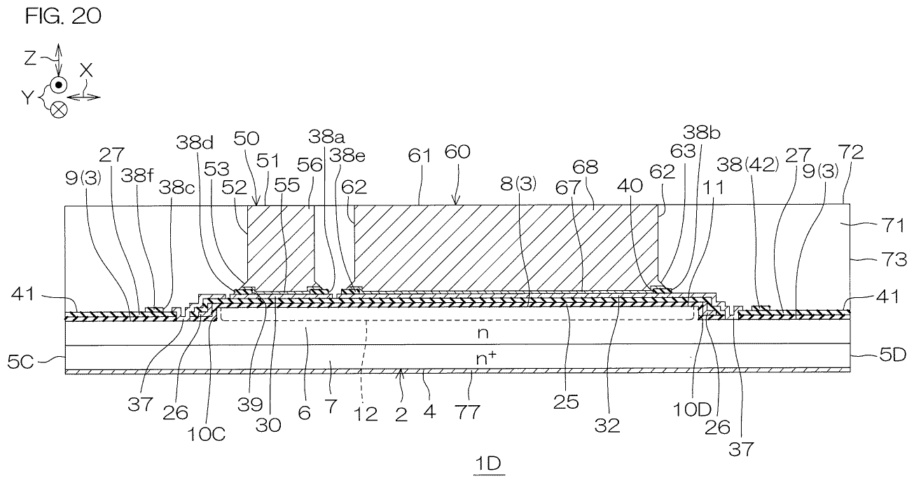

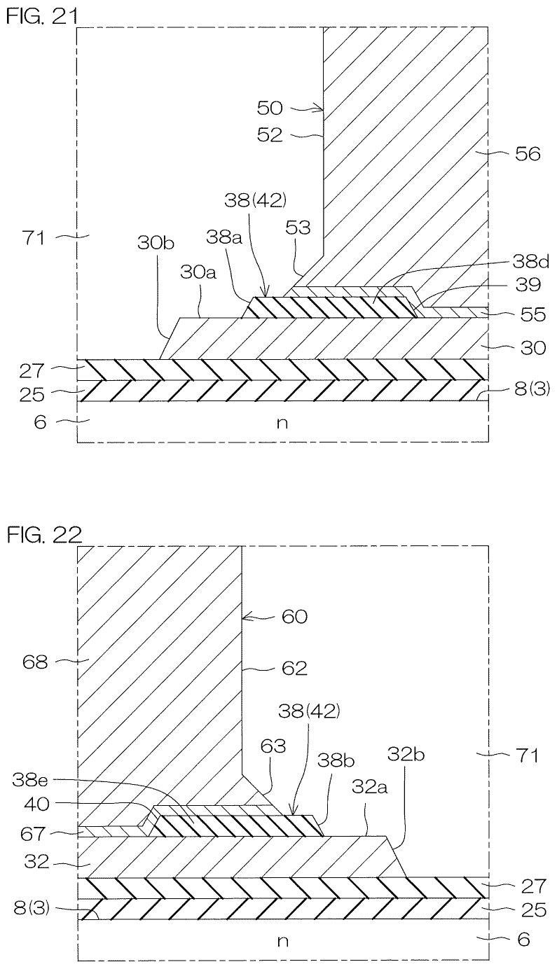

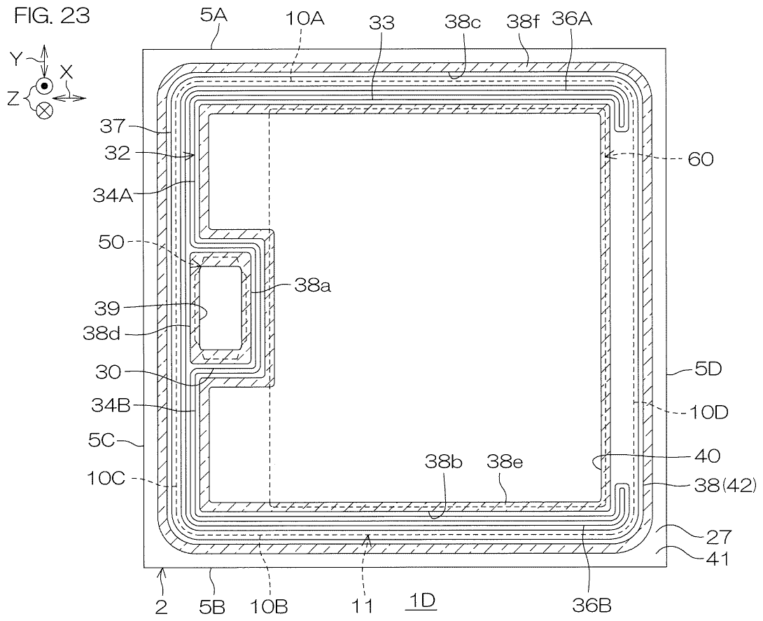

FIG. 20 is a cross sectional view showing a semiconductor device 1D according to a fourth embodiment. FIG. 21 is a cross sectional view showing a main part of the gate terminal electrode 50 shown in FIG. 20. FIG. 22 is a cross sectional view showing a main part of the source terminal electrode 60 shown in FIG. 20. FIG. 23 is a plan view showing a layout example of the upper insulating film 38 shown in FIG. 20. With reference to FIGS. 20 to 23, the semiconductor device 1D has a form in which the aforementioned semiconductor device 1B (see FIG. 13) is deformed. The semiconductor device 1D includes the upper insulating film 38 that has a single layered structure comprising the inorganic insulating film 42, in this embodiment, though may have a single layered structure comprising the organic insulating film 43 instead of the inorganic insulating film 42, as with the case of the aforementioned semiconductor device 1C (see FIG. 18).

The upper insulating film 38 has a gate removal portion 38a that exposes at least a part of the corner portion of the gate electrode 30, in this embodiment. The gate removal portion 38a exposes the whole region of the corner portion of the gate electrode 30, in this embodiment. The gate removal portion 38a exposes the gate electrode surface 30a and the gate electrode side wall 30b at the corner portion of the gate electrode 30.

The upper insulating film 38 has a source removal portion 38b that exposes at least a part of the corner portion of the source electrode 32. The source removal portion 38b exposes the whole region of the corner portion of the source electrode 32, in this embodiment. The source removal portion 38b exposes the source electrode surface 32a and the source electrode side wall 32b at the corner portion of the source electrode 32. The source removal portion 38b is in communication with the gate removal portion 38b in a region between the gate electrode 30 and the source electrode 32, in this embodiment.

The upper insulating film 38 includes a wiring removal portion 38c that exposes the plurality of gate wirings 36A, 36B and the source wiring 37. The wiring removal portion 38c exposes the whole region of the plurality of gate wirings 36A, 36B and the whole region of the source wiring 37, in this embodiment. The wiring removal portion 38c surrounds the gate electrode 30 and the source electrode 32 in plan view, and is in communication with the gate removal portion 38a and the source removal portion 38b, in this embodiment.

The upper insulating film 38 has a gate covering portion 38d that is defined by the gate removal portion 38a on the gate electrode 30. The gate covering portion 38d covers a peripheral edge portion of the gate electrode 30 such as to expose a corner portion of the gate electrode 30 in plan view, and defines the gate opening 39 that exposes an inner portion of the gate electrode 30. The gate covering portion 38d is formed in an annular shape that surrounds the inner portion of the gate electrode 30 in plan view, in this embodiment.

The upper insulating film 38 has a source covering portion 38e that is defined by the source removal portion 38b on the source electrode 32. The source covering portion 38e covers a peripheral edge portion of the source electrode 32 such as to expose a corner portion of the source electrode 32 in plan view, and defines the source opening 40 that exposes an inner portion of the source electrode 32. The source covering portion 38e is formed in an annular shape that surrounds the inner portion of the source electrode 32 in plan view, in this embodiment.

The upper insulating film 38 has an outer covering portion 38f that is defined by the wiring removal portion 38c on the outer surface 9 (the interlayer insulating film 27). The outer covering portion 38f covers a region on the outside of the source wiring 37 in plan view. The outer covering portion 38f is formed in an annular shape that surrounds the active surface 8 (the source wiring 37) in plan view. The aforementioned dicing street 41 is defined in a region between the peripheral edge of the first main surface 3 and the outer covering portion 38f, in this embodiment.

The sealing insulator 71 directly covers the upper insulating film 38 such as to enter the gate removal portion 38a from on the upper insulating film 38, in this embodiment. The sealing insulator 71 directly covers at least a part of the corner portion of the gate electrode 30 within the gate removal portion 38a. The sealing insulator 71 directly covers the whole region of the corner portion of the gate electrode 30, in this embodiment.

The sealing insulator 71 directly covers the gate electrode surface 30a and the gate electrode side wall 30b of the gate electrode 30 within the gate removal portion 38a. The sealing insulator 71 has a portion that directly covers the gate covering portion 38d of the upper insulating film 38 immediately above the gate electrode 30. The sealing insulator 71 may have a portion that faces the gate covering portion 38d with the first protrusion portion 53 of the gate terminal electrode 50 interposed therebetween.

The sealing insulator 71 directly covers the upper insulating film 38 such as to enter the source removal portion 38b from on the upper insulating film 38, in this embodiment. The sealing insulator 71 directly covers at least a part of the corner portion of the source electrode 32 within the source removal portion 38b. The sealing insulator 71 directly covers the whole region of the corner portion of the source electrode 32, in this embodiment.

The sealing insulator 71 directly covers the source electrode surface 32a and the source electrode side wall 32b of the source electrode 32 within the source removal portion 38b. The sealing insulator 71 has a portion that directly covers the source covering portion 38e of the upper insulating film 38 immediately above the source electrode 32. The sealing insulator 71 may have a portion that faces the source covering portion 38e with the second protrusion portion 63 of the source terminal electrode 60 interposed therebetween.

The sealing insulator 71 directly covers the upper insulating film 38 such as to enter the wiring removal portion 38c from on the upper insulating film 38. The sealing insulator 71 directly covers the whole region of the plurality of gate wirings 36A, 36B and the whole region of the source wiring 37 within the wiring removal portion 38c, in this embodiment. The sealing insulator 71 covers the outer covering portion 38f in a region on the outside of the source wiring 37. The sealing insulator 71 directly covers the interlayer insulating film 27 that is exposed outside in the gate removal portion 38, the source removal portion 38b, and the wiring removal portion 38c.

As described above, the same effects as those of the semiconductor device 1B are also achieved with the semiconductor device 1D. The semiconductor device 1D is manufactured by changing the layout of the upper insulating film 38 in the manufacturing method for the semiconductor device 1B (the semiconductor device 1C). Accordingly, the same effects as those of the manufacturing method for the semiconductor device 1B are also achieved with the manufacturing method for the semiconductor device 1D.

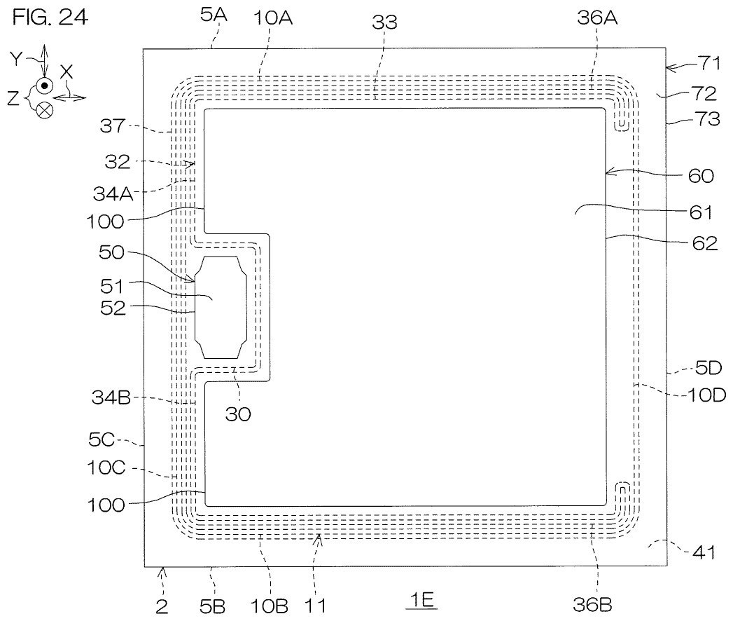

FIG. 24 is a plan view showing a semiconductor device 1E according to a fifth embodiment. With reference to FIG. 24, the semiconductor device 1E has a modified mode of the semiconductor device 1A. Specifically, the semiconductor device 1E includes the source terminal electrode 60 that has at least one (in this embodiment, a plurality of) drawer terminal portions 100. Specifically, the plurality of drawer terminal portions 100 are each drawn out onto the plurality of drawer electrode portions 34A, 34B of the source electrode 32 such as to oppose the gate terminal electrode 50 in the second direction Y. That is, the plurality of drawer terminal portions 100 sandwich the gate terminal electrode 50 from both sides of the second direction Y in plan view.

As described above, the same effects as those of the semiconductor device 1E are also achieved with the semiconductor device 1E. Also, the semiconductor device 1E is manufactured through the similar manufacturing method to the manufacturing method for the semiconductor device 1A. Therefore, the same effects as those of the manufacturing method for the semiconductor device 1A are also achieved with the manufacturing method for the semiconductor device 1E. In this embodiment, an example in which the drawer terminal portion 100 is applied to the semiconductor device 1A. As a matter of course, the drawer terminal portion 100 may be applied to the second and fourth embodiments.

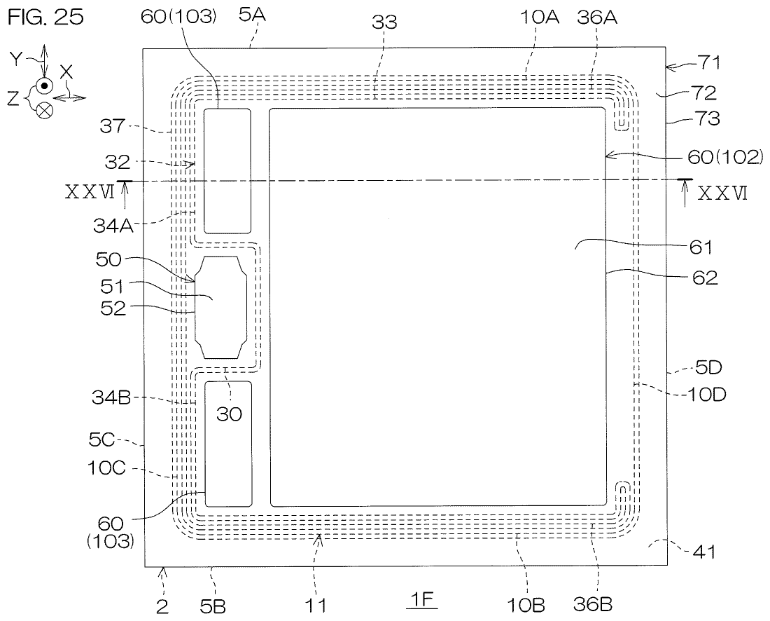

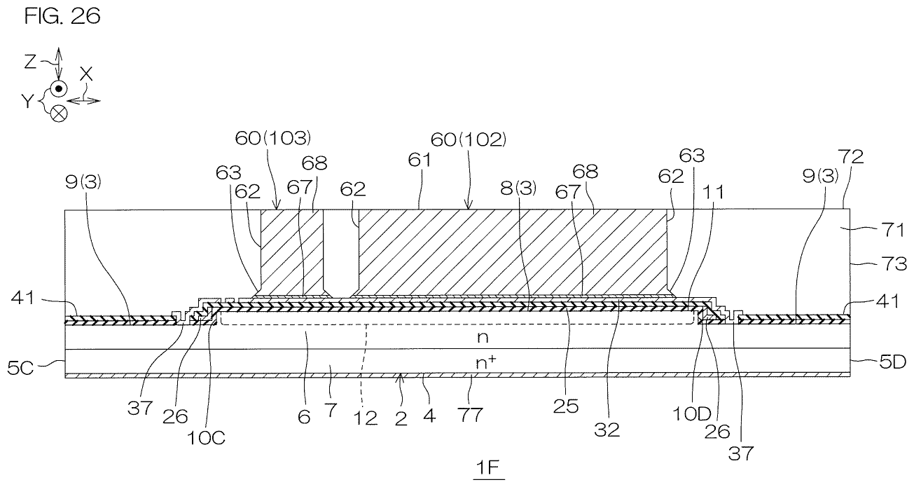

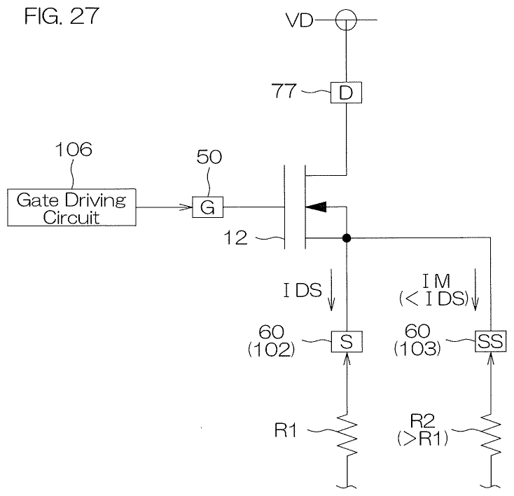

FIG. 25 is a plan view showing a semiconductor device 1F according to a sixth embodiment. FIG. 26 is a cross sectional view taken along XXVI-XXVI line shown in FIG. 27. FIG. 27 is a circuit diagram showing an electrical configuration of the semiconductor device 1F shown in FIG. 25. With reference to FIG. 25 to FIG. 27, the semiconductor device 1F has a modified mode of the semiconductor device 1A.

Specifically, the semiconductor device 1F includes the plurality of source terminal electrodes 60 that are arranged on the source electrode 32 at intervals from each other. The semiconductor device 1F includes at least one (in this embodiment, one) source terminal electrode 60 that is arranged on the body electrode portion 33 of the source electrode 32 and at least one (in this embodiment, a plurality of) source terminal electrodes 60 that are arranged on the plurality of drawer electrode portions 34A, 34B of the source electrode 32, in this embodiment.

The source terminal electrode 60 on the body electrode portion 33 side is formed as a main terminal electrode 102 that conducts a drain source current IDS, in this embodiment. The plurality of source terminal electrodes 60 on the plurality of drawer electrode portions 34A, 34B sides are each formed as a sense terminal electrode 103 that conducts a monitor current IM which monitors the drain source current IDS, in this embodiment. Each of the sense terminal electrodes 103 has an area less than an area of the main terminal electrode 102 in plan view.

One sense terminal electrode 103 is arranged on the first drawer electrode portion 34A and faces the gate terminal electrode 50 in the second direction Y in plan view. The other sense terminal electrode 103 is arranged on the second drawer electrode portion 34B and faces the gate terminal electrode 50 in the second direction Y in plan view. The plurality of sense terminal electrodes 103 therefore sandwich the gate terminal electrode 50 from both sides of the second direction Y in plan view.

With reference to FIG. 27, in the semiconductor device 1F, a gate driving circuit 106 is to be electrically connected to the gate terminal electrode 50, at least one first resistance R1 is to be electrically connected to the main terminal electrode 102, and at least one second resistance R2 is to be electrically connected to the plurality of sense terminal electrodes 103. The first resistance R1 is configured such as to conduct the drain source current IDS that is generated in the semiconductor device 1F. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to the main terminal electrode 102.

Also, at least one second bonding wire with the second resistance value more than the first resistance value may be connected to at least one of the sense terminal electrodes 103. The second bonding wire may have a line thickness less than a line thickness of the first bonding wire. In this case, a bonding area of the second bonding wire with respect to the sense terminal electrode 103 may be less than a bonding area of the first bonding wire with respect to the main terminal electrode 102.

As described above, the same effects as those of the semiconductor device 1A are also achieved with the semiconductor device 1F. In the manufacturing method for the semiconductor device 1F, the resist mask 90 having the plurality of second openings 92 that exposes regions in each of which the source terminal electrode 60 and the sense terminal electrode 103 are to be formed is formed in the manufacturing method for the semiconductor device 1A, and then the same steps as those of the manufacturing method for the semiconductor device 1A are performed. Therefore, the same effects as those of the manufacturing method for the semiconductor device 1A are also achieved with the manufacturing method for the semiconductor device 1F.

In this embodiment, an example in which the sense terminal electrodes 103 are formed on the drawer electrode portions 34A, 34B, but the arrangement locations of the sense terminal electrodes 103 are arbitrary. Therefore, the sense terminal electrode 103 may be arranged on the body electrode portion 33. In this embodiment, an example in which the sense terminal electrode 103 is applied to the semiconductor device 1A has been shown. As a matter of course, the sense terminal electrode 103 may be applied to the second to fifth embodiments.

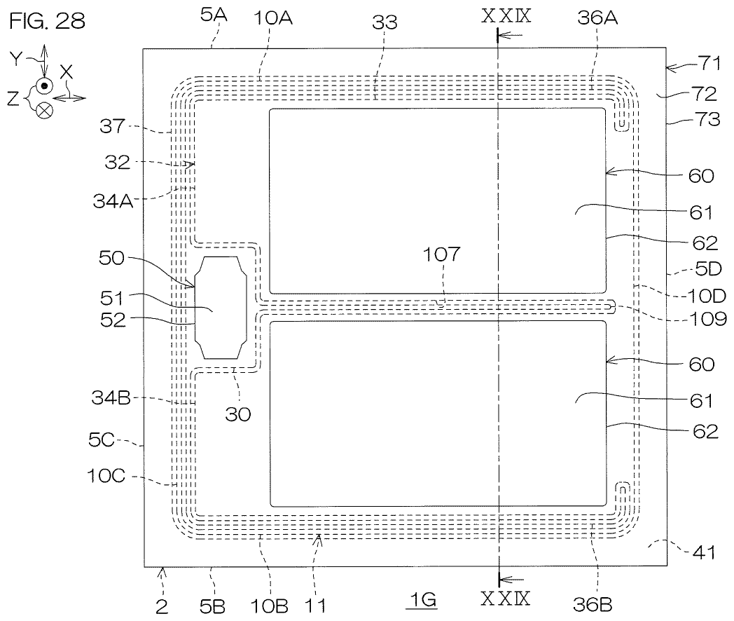

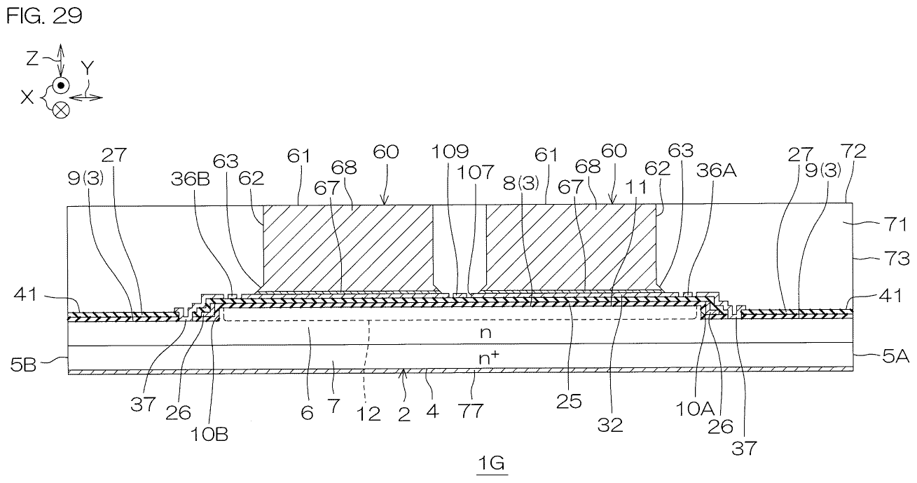

FIG. 28 is a plan view showing a semiconductor device 1G according to a seventh embodiment. FIG. 29 is a cross sectional view taken along XXIX-XXIX line shown in FIG. 28. With reference to FIG. 28 and FIG. 29, the semiconductor device 1G has a modified mode of the semiconductor device 1A. Specifically, the semiconductor device 1G includes a gap portion 107 that formed in the source electrode 32.

The gap portion 107 is formed in the body electrode portion 33 of the source electrode 32. The gap portion 107 penetrates the source electrode 32 to expose a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may divide the source electrode 32 into the second direction Y.

The semiconductor device 1G includes a gate intermediate wiring 109 that is drawn out into the gap portion 107 from the gate electrode 30. The gate intermediate wiring 109 has a laminated structure that includes the first gate conductor film 55 and the second gate conductor film 56 as with the gate electrode 30 (the plurality of gate wiring 36A, 36B). The gate intermediate wiring 109 is formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The semiconductor device 1G includes the plurality of source terminal electrodes 60 that are arranged on the source electrode 32 at an interval from each other, in this embodiment. The plurality of source terminal electrodes 60 are each arranged on the source electrode 32 at an interval from the gap portion 107 and face each other in the second direction Y in plan view.

The plurality of source terminal electrodes 60 are each formed in a quadrangle shape (specifically, rectangular shape extending in the first direction X) in plan view, in this embodiment. The planar shapes of the plurality of source terminal electrodes 60 is arbitrary, and may each be formed in a polygonal shape other than the quadrangle shape, a circular shape, or an elliptical shape in plan view.

The aforementioned sealing insulator 71 covers the gap portion 107 in a region between the plurality of source terminal electrodes 60, in this embodiment. The sealing insulator 71 directly covers the gate intermediate wiring 109 in the region between the plurality of source terminal electrodes 60. The sealing insulator 71 directly covers at least a part (the whole region in this embodiment) of the corner portion of the source electrode 32 in the region between the plurality of source terminal electrodes 60. That is, the sealing insulator 71 directly covers the source electrode surface 32a and the source electrode side wall 32b of the source electrode 32 in the region between the plurality of source terminal electrodes 60.

As described above, the same effects as those of the semiconductor device 1A are also achieved with the semiconductor device 1G. In the manufacturing method for the semiconductor device 1G, the wafer structure 80 in which structures corresponding to the semiconductor device 1G are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1G.

In this embodiment, an example is illustrated in which the gap portion 107 and the gate intermediate wiring 109, for example, are applied to the semiconductor device 1A. As a matter of course, the gap portion 107 and the gate intermediate wiring 109, for example, may be applied in the second to sixth embodiments. For example, the semiconductor device 1G may include the upper insulating film 38 according to the second to fourth embodiments. In this case, the upper insulating film 38 may include a portion that covers the gap portion 107.

It is preferable that the upper insulating film 38 directly covers the whole region of the gate intermediate wiring 109 within the gap portion 107. It is also preferable that the upper insulating film 38 directly covers at least a part (the whole region in this embodiment) of the corner portion of the source electrode 32 within the gap portion 107. That is, it is preferable that the upper insulating film 38 directly covers the source electrode surface 32a and the source electrode side wall 32b within the gap portion 107.

The plurality of source terminal electrodes 60 are preferably arranged such as to expose a portion of the upper insulating film 38 that covers the gap portion 107. The plurality of source terminal electrodes 60 may include the second protrusion portion 63 that is formed on the portion of the upper insulating film 38 that covers the gap portion 107.

The sealing insulator 71 may directly cover the upper insulating film 38 in the region between the plurality of source terminal electrodes 60. That is, the sealing insulator 71 may cover the gate intermediate wiring 109 with the upper insulating film 38 interposed therebetween. The sealing insulator 71 may cover the corner portion of the source electrode 32 with the upper insulating film 38 interposed therebetween in the region between the plurality of source terminal electrodes 60.

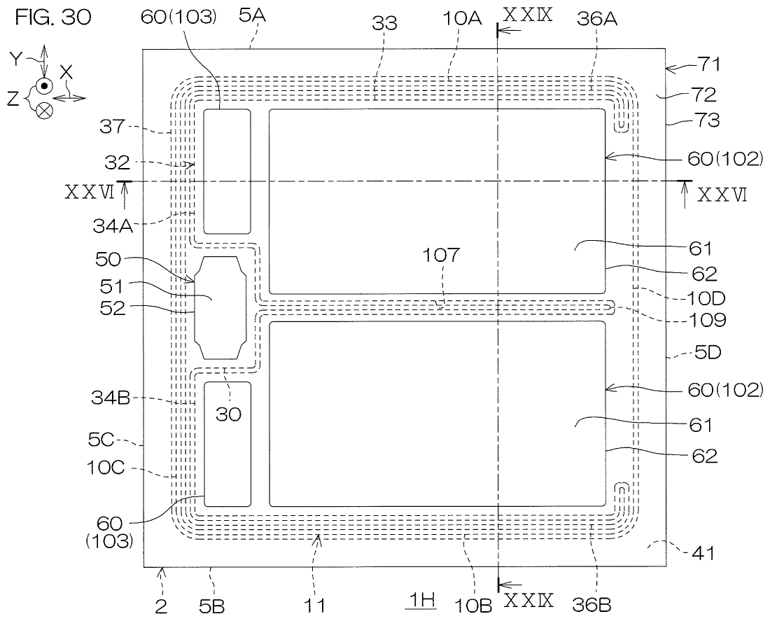

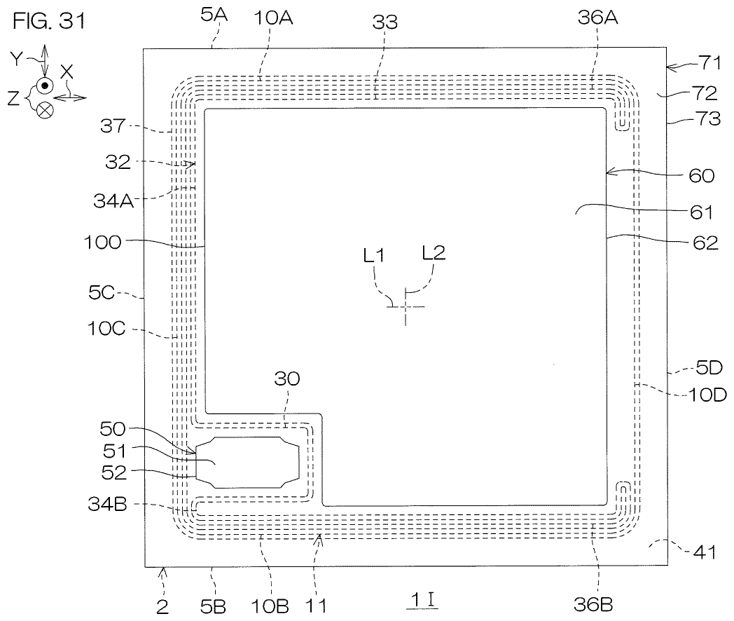

FIG. 30 is a plan view showing a semiconductor device 1H according to an eighth embodiment. With reference to FIG. 30, the semiconductor device 1H has a mode in which the features (structures having the gate intermediate wiring 109) of the semiconductor device 1G according to the seventh embodiment are combined to the features (structures having the sense terminal electrode 103) of the semiconductor device 1F according to the sixth embodiment. The same effects as those of the semiconductor device 1A are also achieved with the semiconductor device 1H having such a mode.

FIG. 31 is a plan view showing a semiconductor device 1I according to a ninth embodiment. With reference to FIG. 31, the semiconductor device 1I has a modified mode of the semiconductor device 1A. Specifically, the semiconductor device 1I has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 50 aforementioned is arranged on the gate electrode 30 as with the case of the first embodiment. The gate terminal electrode 50 is arranged at a region along an arbitrary corner portion of the chip 2, in this embodiment. That is, the gate terminal electrode 50 is arranged at a position offset from both of the first straight line L1 and the second straight line L2 in plan view. The gate terminal electrode 50 is arranged at the region along the corner portion that connects the second side surface 5B and the third side surface 5C in plan view, in this embodiment.

The source terminal electrode 60 aforementioned has the drawer terminal portion 100 that is drawn out onto the first drawer electrode portion 34A, in this embodiment. The source terminal electrode 60 does not have the drawer terminal portion 100 that is drawn out onto the second drawer electrode portion 34B, in this embodiment. The drawer terminal portions 100 thereby faces the gate terminal electrode 50 from one side of the second direction Y. The source terminal electrode 60 has portions that face the gate terminal electrode 50 from two directions including the first direction X and the second direction Y by having the drawer terminal portion 100.

As described above, the same effects as those of the semiconductor device 1A are also achieved with the semiconductor device 1I. In the manufacturing method for the semiconductor device 1I, the wafer structure 80 in which structures corresponding to the semiconductor device 1I are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1I. The structure in which the gate electrode 30 and the gate terminal electrode 50 are arranged at the corner portion of the chip 2 may be applied to the second to eighth embodiments.

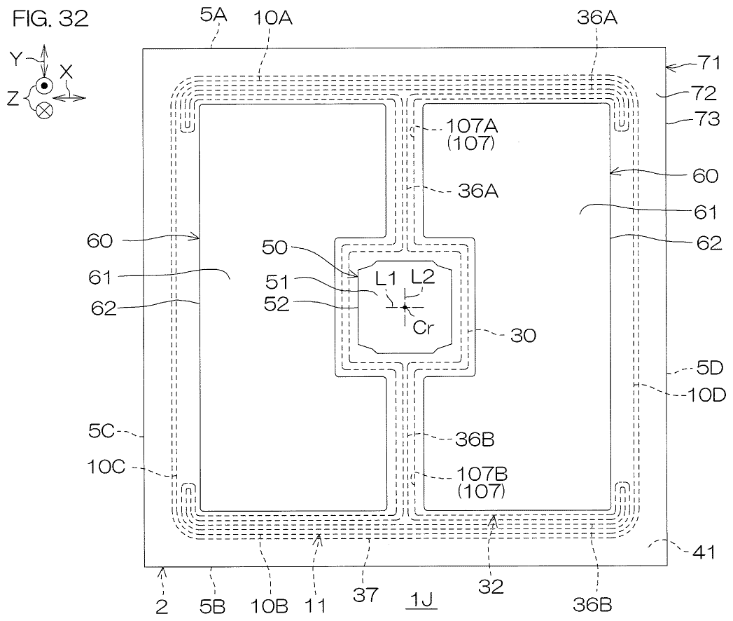

FIG. 32 is a plan view showing a semiconductor device 1J according to a tenth embodiment. With reference to FIG. 32, the semiconductor device 1J has a modified mode of the semiconductor device 1A. Specifically, the semiconductor device 1J has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 aforementioned is formed in an annular shape (specifically, a quadrangle annular shape) surrounding the gate electrode 30 in plan view, in this embodiment.

The semiconductor device 1J includes a plurality of gap portions 107A, 107B that are formed in the source electrode 32. The plurality of gap portions 107A, 107B includes a first gap portions 107A and a second gap portions 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The gate terminal electrode 50 aforementioned is arranged on the gate electrode 30 as with the case of the first embodiment. The gate terminal electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 50 is arranged such as to overlap the intersecting portion Cr of the first straight line L1 and the second straight line L2.

The semiconductor device 1J includes a plurality of source terminal electrodes 60 that are arranged on the source electrode 32, in this embodiment. The plurality of source terminal electrodes 60 are each arranged on the source electrode 32 at intervals from the plurality of gap portions 107A, 107B and face each other in the first direction X in plan view. The plurality of source terminal electrodes 60 are arranged such as to expose the plurality of gap portions 107A, 107B, in this embodiment.

The plurality of source terminal electrodes 60 are each formed in a band shape (specifically, C-letter shape curved along the gate terminal electrode 50) in plan view, in this embodiment. The planar shapes of the plurality of source terminal electrodes 60 are arbitrary, and may each be formed in a quadrangle shape, a polygonal shape other than the quadrangle shape, a circular shape or an elliptical shape.

The aforementioned sealing insulator 71 covers the plurality of gap portions 107A, 107B in a region between the plurality of source terminal electrodes 60, in this embodiment. The sealing insulator 71 directly covers the plurality of gate wirings 36A, 36B in the region between the plurality of source terminal electrodes 60. The sealing insulator 71 directly covers at least a part (the whole region in this embodiment) of the corner portion of the source electrode 32 in the region between the plurality of source terminal electrodes 60. That is, the sealing insulator 71 directly covers the source electrode surface 32a and the source electrode side wall 32b of the source electrode 32 in the region between the plurality of source terminal electrodes 60.

As described above, the same effects as those of the semiconductor device 1A are also achieved with the semiconductor device 1J. In the manufacturing method for the semiconductor device 1J, the wafer structure 80 in which structures corresponding to the semiconductor device 1J are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1J.

The structure in which the gate electrode 30 and the gate terminal electrode 50 are arranged in the central portion of the chip 2 may be applied to the second to ninth embodiments. For example, the semiconductor device 1J may include the upper insulating film 38 according to the second to fourth embodiments. In this case, the upper insulating film 38 may include a portion that covers the plurality of gap portions 107A, 107B.

It is preferable that the upper insulating film 38 directly covers the whole region of the plurality of gate wirings 36A, 36B within the plurality of gap portions 107A, 107B. It is also preferable that the upper insulating film 38 directly covers at least a part (preferably the whole region) of the corner portion of the source electrode 32 within the plurality of gap portions 107A, 107B. That is, it is preferable that the upper insulating film 38 directly covers the source electrode surface 32a and the source electrode side wall 32b within the plurality of gap portions 107A, 107B.

The plurality of source terminal electrodes 60 are preferably arranged such as to expose a portion of the upper insulating film 38 that covers the gap portion 107. The plurality of source terminal electrodes 60 may include the second protrusion portion 63 that is formed on the portion of the upper insulating film 38 that covers the gap portion 107.

The sealing insulator 71 may directly cover the upper insulating film 38 in the region between the plurality of source terminal electrodes 60. That is, the sealing insulator 71 may cover the plurality of gate wirings 36A, 36B with the upper insulating film 38 interposed therebetween. The sealing insulator 71 preferably covers the corner portion of the source electrode 32 with the upper insulating film 38 interposed therebetween in the region between the plurality of source terminal electrodes 60.

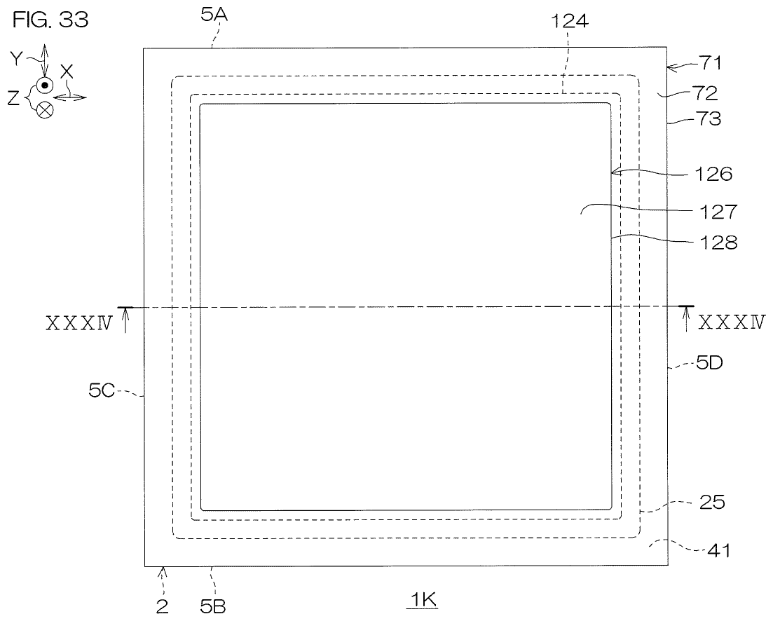

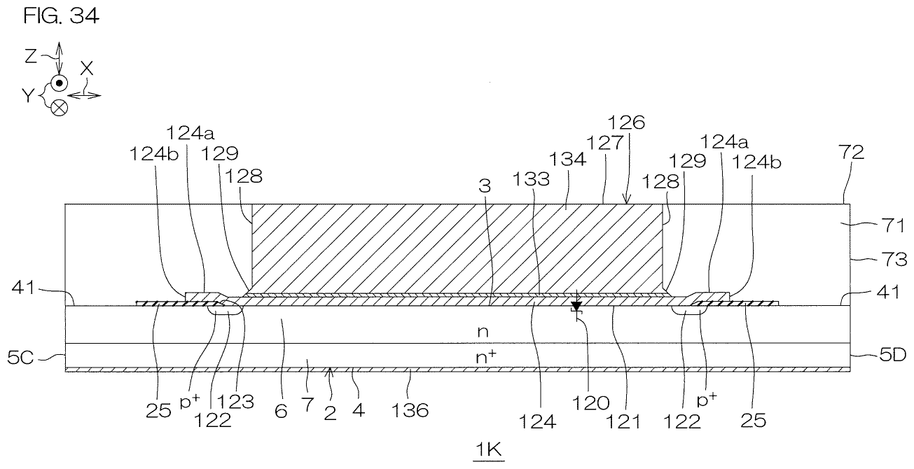

FIG. 33 is a plan view showing a semiconductor device 1K according to an eleventh embodiment. FIG. 34 is a cross sectional view taken along XXXIV-XXXIV line shown in FIG. 33. The semiconductor device 1K includes the chip 2 aforementioned. The chip 2 is free from the mesa portion 11 in this embodiment and has the flat first main surface 3. The semiconductor device 1K has an SBD (Schottky Barrier Diode) structure 120 that is formed in the chip 2 as an example of a diode.

The semiconductor device 1K includes a diode region 121 of the n-type that is formed in an inner portion of the first main surface 3. The diode region 121 is formed by using a part of the first semiconductor region 6, in this embodiment.

The semiconductor device 1K includes a guard region 122 of the p-type that demarcates the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1K includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1K includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 has an electrode surface 124a and an electrode side wall 124b. The electrode surface 124a extends along the first main surface 3 and the main surface insulating film 25. The electrode side wall 124b is positioned on the main surface insulating film 25. The electrode side wall 124b may extend in a manner obliquely inclined or substantially vertical with respect to the main surface insulating film 25.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1K includes a terminal electrode 126 that is arranged on the first polar electrode 124. The terminal electrode 126 is erected in a columnar shape on the first polar electrode 124. The terminal electrode 126 has an area less than the area of the first polar electrode 124 in plan view, and arranged on an inner portion of the first polar electrode 124 at an interval from the peripheral edge of the first polar electrode 124. That is, the terminal electrode 126 exposes at least a part of a corner portion (peripheral edge portion) of the first polar electrode 124.

The terminal electrode 126 exposes the corner portion of the first polar electrode 124 over the entire circumference, in this embodiment. Specifically, the terminal electrode 126 exposes the electrode surface 124a and the electrode side wall 124b at the corner portion of the first polar electrode 124. The terminal electrode 126 has a lower end that is only connected to the electrode surface 124a on the first polar electrode 124. The terminal electrode 126 is formed in a polygonal shape (quadrilateral shape in this embodiment) that has four sides in parallel with the first to fourth side surfaces 5A to 5D in plan view, in this embodiment.

The terminal electrode 126 has a terminal surface 127 and a terminal side wall 128. The terminal surface 127 flatly extends along the first main surface 3. The terminal surface 127 may consist of a grinding surface that has a grinding mark. The terminal side wall 128 is positioned on the terminal electrode 126 and extends substantially vertically in the normal direction Z, in this embodiment. Here, “substantially vertically” includes a mode that extends in the laminate direction while being curved (meandering). The terminal side wall 128 preferably consists of a smooth surface without a grinding mark.

The terminal electrode 126 has a protrusion portion 129 that outwardly protrudes at a lower end portion of the terminal side wall 128. The protrusion portion 129 is formed at a region on the first polar electrode 124 side than an intermediate portion of the terminal side wall 128. The protrusion portion 129 extends along the electrode surface 124a of the first polar electrode 124, and is formed in a tapered shape in which a thickness gradually decreases toward the tip portion from the terminal side wall 128 in cross sectional view. The protrusion portion 129 therefore has a sharp-shaped tip portion with an acute angle. As a matter of course, the protrusion portion 129 without the protrusion portion 129 may be formed.

The terminal electrode 126 preferably has a thickness exceeding the thickness of the first polar electrode 124. The thickness of the terminal electrode 126 exceeds the thickness of the chip 2, in this embodiment. As a matter of course, the thickness of the terminal electrode 126 may be less than the thickness of the chip 2. The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm. The terminal electrode 126 preferably has a planar area of not less than 50% of the first main surface 3. The terminal electrode 126 particularly preferably has a planar area of not less than 75% of the first main surface 3.

The terminal electrode 126 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape. The first conductor film 133 forms a part of the protrusion portion 129. The first conductor film 133 does not necessarily have to be formed and may be omitted.

The second conductor film 134 forms a body of the terminal electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 exceeds the thickness of the chip 2, in this embodiment.

The second conductor film 134 covers the first polar electrode 124 with the first conductor film 133 interposed therebetween. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The semiconductor device 1K includes the dicing street 41 that is provided in a region between the peripheral edge of the first main surface 3 and the first polar electrode 124. The dicing street 41 is provided in a region between the peripheral edge of the first main surface 3 and the main surface insulating film 25, in this embodiment. The dicing street 41 is formed in a band shape extending along the peripheral edge of the first main surface 3 in plan view, and that exposes the first main surface 3.

The dicing street 41 is formed in an annular shape (specifically, quadrilateral annular shape) that surrounds the inner portion of the first main surface 3 in plan view, in this embodiment. In a case in which the main surface insulating film 25 is formed to be continuous with the peripheral edge of the first main surface 3, the dicing street 41 exposes the main surface insulating film 25 in a region between the peripheral edge of the first main surface 3 and the first polar electrode 124.

The semiconductor device 1K includes the sealing insulator 71 aforementioned that covers the first main surface 3. The sealing insulator 71 covers a periphery of the terminal electrode 126 such as to expose a part of the terminal electrode 126 on the first main surface 3, in this embodiment. Specifically, the sealing insulator 71 exposes the terminal surface 127 and covers the terminal side wall 128. The sealing insulator 71 covers the protrusion portion 129 and faces the terminal electrode 126 with the protrusion portion 129 interposed therebetween, in this embodiment. The sealing insulator 71 suppresses a dropout of the terminal electrode 126.

The sealing insulator 71 has a portion that directly covers the first polar electrode 124 on a lower end portion side of the terminal electrode 126. Specifically, the sealing insulator 71 has a portion that directly covers at least a part of a corner portion of the first polar electrode 124. The sealing insulator 71 directly covers the whole region of the corner portion of the first polar electrode 124, in this embodiment.

The sealing insulator 71 directly covers the electrode surface 124a and the electrode side wall 124b at the corner portion of the first polar electrode 124. That is, the sealing insulator 71 has a portion in contact only with the first polar electrode 124 (the electrode surface 124a) and the gate terminal electrode 50 (the electrode side wall 124b) immediately above the first polar electrode 124. A portion of the sealing insulator 71 that directly covers the electrode side wall 124b is in contact with the main surface insulating film 25.

The sealing insulator 71 covers the dicing street 41 defined by the main surface insulating film 25 at the peripheral edge of the first main surface 3 . . . . The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 preferably has a thickness exceeding the thickness of the first polar electrode 124. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

The sealing insulator 71 has the insulating main surface 72 and the insulating side wall 73. The insulating main surface 72 flatly extends along the first main surface 3. The insulating main surface 72 forms a single flat surface with the terminal surface 127. The insulating main surface 72 may consist of a ground surface with grinding marks. In this case, the insulating main surface 72 preferably forms a single ground surface with the terminal surface 127.

The insulating side wall 73 extends toward the chip 2 from the peripheral edge of the insulating main surface 72 and is continuous to the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The semiconductor device 1K includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 and second polar electrode 136. That is, the chip 2 is formed such that the voltage of not less than 500 V and not more than 3000 V is to be applied between the first main surface 3 and the second main surface 4.

As described above, the semiconductor device 1K includes the chip 2, the first polar electrode 124 (main surface electrode), the terminal electrode 126 and the sealing insulator 71. The chip 2 has the first main surface 3. The first polar electrode 124 is arranged on the first main surface 3. The terminal electrode 126 is arranged on the first polar electrode 124 such as to expose a part of the first polar electrode 124. The sealing insulator 71 covers the periphery of the terminal electrode 126 such as to expose a part of the terminal electrode 126, and has the portion directly covering the first polar electrode 124.

In accordance with the structure above, since no other member is interposed between the first polar electrode 124 and the sealing insulator 71, the starting points for peel-off between the first polar electrode 124 and the sealing insulator 71 can be reduced. This allows the sealing insulator 71 to adequately protect a sealing target (e.g. the first polar electrode 124). That is, it is possible to protect the sealing target from damage due to an external force and/or degradation due to moisture. This allows for shape defects and variations in the electrical properties to be suppressed. It is therefore possible to provide the semiconductor device 1K capable of improving reliability.

It is preferable that the terminal electrode 126 exposes the corner portion of the first polar electrode 124, and that the sealing insulator 71 directly covers at least a part of the corner portion of the first polar electrode 124. That is, it is preferable that the terminal electrode 126 exposes the electrode surface 124a and the electrode side wall 124b, and that the sealing insulator 71 directly covers the electrode surface 124a and the electrode side wall 124b. In accordance with the structures above, it is possible to reduce the peel-off starting points at the corner portion of the first polar electrode 124, and to suppress ingress of moisture or the like starting at the corner portion of the first electrode 124. The sealing insulator 71 preferably has a portion in contact only with the first polar electrode 124 and the terminal electrode 126.

The same effects as those of the semiconductor device 1A are thus achieved with the semiconductor device 1K. In the manufacturing method for the semiconductor device 1K, the wafer structure 80 is prepared with a structure corresponding to that of the semiconductor device 1K built in the device region 86, and the same steps as those in the manufacturing method for the semiconductor device 1A are performed. Accordingly, the same effects as those of the manufacturing method for the semiconductor device 1A are also achieved with the manufacturing method for the semiconductor device 1K.

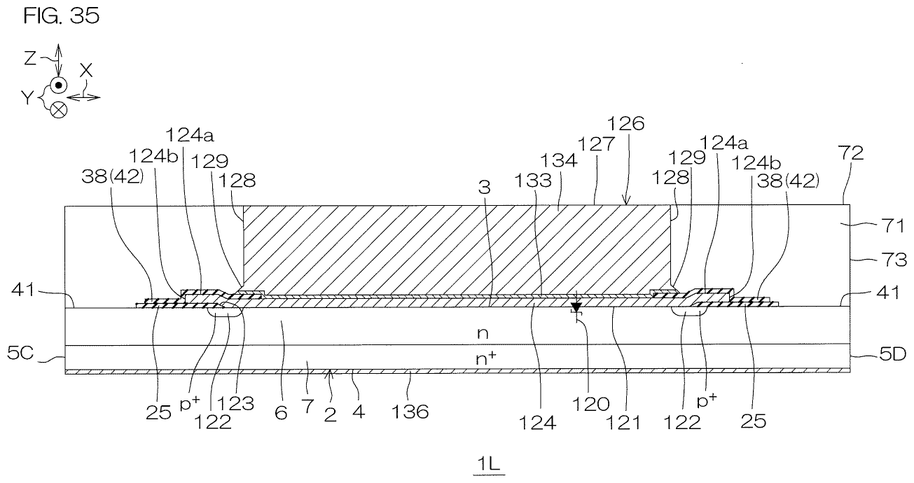

FIG. 35 is a plan view showing a semiconductor device 1L according to a twelfth embodiment. The semiconductor device 1L has a form in which the technical idea of the semiconductor device 1B according to the second embodiment (see FIG. 13) is incorporated into the aforementioned semiconductor device 1K (see FIGS. 33 and 34). That is, the semiconductor device 1L has the single layered structure comprising the inorganic insulating film 42 (inorganic film) and includes the upper insulating film 38 that directly covers the first polar electrode 124. It is particularly preferable that the inorganic insulating film 42 has a thickness less than the thickness of the first polar electrode 124.

The upper insulating film 38 has a contact opening 125 that exposes an inner portion of the first polar electrode 124, and has a portion that directly covers at least a part of a corner portion (peripheral edge portion) of the first polar electrode 124. The upper insulating film 38 directly covers the whole region of the corner portion of the first polar electrode 124, in this embodiment. The upper insulating film 38 directly covers the electrode surface 124a and the electrode side wall 124b at the corner portion of the first polar electrode 124. A portion of the upper insulating film 38 that directly covers the electrode side wall 124b is in contact with the main surface insulating film 25. The contact opening 125 is formed in a quadrilateral shape in plan view, in this embodiment.

The upper insulating film 38 is formed at an interval inward from the peripheral edge (the first to fourth side surfaces 5A to 5D) of the first main surface 3, and defines the dicing street 41 with the peripheral edge of the first main surface 3. The dicing street 41 is formed in a band shape that extends along the peripheral edge of the first main surface 3 in plan view. The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25.

The terminal electrode 126 has an area less than the area of the first polar electrode 124 in plan view, and is arranged on the inner portion of the first polar electrode 124 at an interval from the peripheral edge of the first polar electrode 124 as with the case of the eleventh embodiment. The terminal electrode 126 has a thickness that exceeds the thickness of the upper insulating film 38, in this embodiment.

The terminal electrode 126 extends from on the first polar electrode 124 onto the upper insulating film 38 and directly covers the first polar electrode 124 and the upper insulating film 38. Specifically, the terminal electrode 126 exposes a portion in the upper insulating film 38 that covers the corner portion (i.e. the electrode surface 124a and the electrode side wall 124b) of the first polar electrode 124.

The terminal side wall 128 of the terminal electrode 126 is positioned on the upper insulating film 38 and extends substantially vertically in the normal direction Z, in this embodiment. The terminal side wall 128 faces the first polar electrode 124 with the upper insulating film 38 interposed therebetween. The protrusion portion 129 of the terminal electrode 126 extends along the outer surface of the upper insulating film 38, and is formed in a tapered shape in which the thickness gradually decreases from the terminal side wall 128 toward the tip portion in cross-sectional view, in this embodiment.

The terminal electrode 126 has a laminated structure that includes the first conductor film 133 and the second conductor film 134 as with the case of the eleventh embodiment. The first conductor film 133 covers the first polar electrode 124 in a film shape within the contact opening 125, and is drawn out in a film shape on the upper insulating film 38, in this embodiment. The second conductor film 134 covers the first polar electrode 124 with the first conductor film 133 interposed therebetween within the contact opening 125, and is drawn out in a film shape on the upper insulating film 38 with the first conductor film 133 interposed therebetween, in this embodiment.

The sealing insulator 71 has a portion that directly covers the upper insulating film 38, in this embodiment. The sealing insulator 71 has a portion that directly covers the upper insulating film 38 on the terminal electrode 126. That is, the sealing insulator 71 has a portion that covers the terminal electrode 126 with the upper insulating film 38 interposed therebetween. Specifically, the sealing insulator 71 has a portion that covers at least a part of a corner portion of the terminal electrode 126 with the upper insulating film 38 interposed therebetween.

The sealing insulator 71 covers the whole region of the corner portion of the first polar electrode 124 with the upper insulating film 38 interposed therebetween, in this embodiment. The sealing insulator 71 covers the electrode surface 124a and the electrode side wall 124b at the corner portion of the first polar electrode 124 with the upper insulating film 38 interposed therebetween. The sealing insulator 71 is formed on the upper insulating film 38 at an interval from the contact opening 125 toward the corner portion of the first polar electrode 124, in this embodiment.

That is, the sealing insulator 71 has a portion in contact only with the upper insulating film 38 and the terminal electrode 126 (the terminal side wall 128) immediately above the first polar electrode 124, and does not have a portion that directly covers the first polar electrode 124, in this embodiment. The sealing insulator 71 covers the protrusion portion 129 of the terminal electrode 126, and has a portion that faces the upper insulating film 38 with the protrusion portion 129 interposed therebetween, in this embodiment.

As described above, the semiconductor device 1L includes the chip 2, the first polar electrode 124 (the main surface electrode), the terminal electrode 126, the upper insulating film 38 (the insulating film), and the sealing insulator 71. The chip 2 has the first main surface 3. The first polar electrode 124 is arranged on the first main surface 3. The upper insulating film 38 has the single layered structure comprising the inorganic insulating film 42 (the inorganic film) and directly covers the first polar electrode 124 such as to expose a part of the first polar electrode 124. The terminal electrode 126 is arranged on the first polar electrode 124. The sealing insulator 71 covers a periphery of the terminal electrode 126 such as to expose a part of the terminal electrode 126, and has the portion that directly covers the upper insulating film 38.

In accordance with the structure above, the upper insulating film 38 allows the first polar electrode 124 to be protected from an external force and/or moisture. Also, in accordance with the structure above, since no laminated film is interposed between the first polar electrode 124 and the sealing insulator 71, it is possible to reduce the peel-off starting points between the first polar electrode 124 and the sealing insulator 71.

This allows both the upper insulating film 38 and the sealing insulator 71 to adequately protect a sealing target (e.g. the first polar electrode 124). That is, it is possible to protect the sealing target (e.g. the first polar electrode 124) from damage due to an external force and/or degradation due to moisture. This allows for shape defects and variations in the electrical properties to be suppressed. It is therefore possible to provide the semiconductor device 1L capable of improving reliability.

It is preferable that the upper insulating film 38 directly covers at least a part of the corner portion of the first polar electrode 124. That is, it is preferable that the upper insulating film 38 directly covers the electrode surface 124a and the electrode side wall 124b of the first polar electrode 124. In accordance with this structure, it is possible to reduce the peel-off starting points at the corner portion of the first polar electrode 124, and to adequately reduce ingress of moisture or the like starting at the corner portion of the first polar electrode 124.

In this case, the sealing insulator 71 preferably covers at least a part of the corner portion of the first polar electrode 124 with the upper insulating film 38 interposed therebetween. That is, the sealing insulator 71 preferably covers the electrode surface 124a and the electrode side wall 124b with the upper insulating film 38 interposed therebetween. In accordance with the structure above, both the upper insulating film 38 and the sealing insulator 71 allow the corner portion of the first polar electrode 124 to be protected adequately. The terminal electrode 126 preferably has a portion that is positioned on the first polar electrode 124 and a portion that is positioned on the upper insulating film 38.

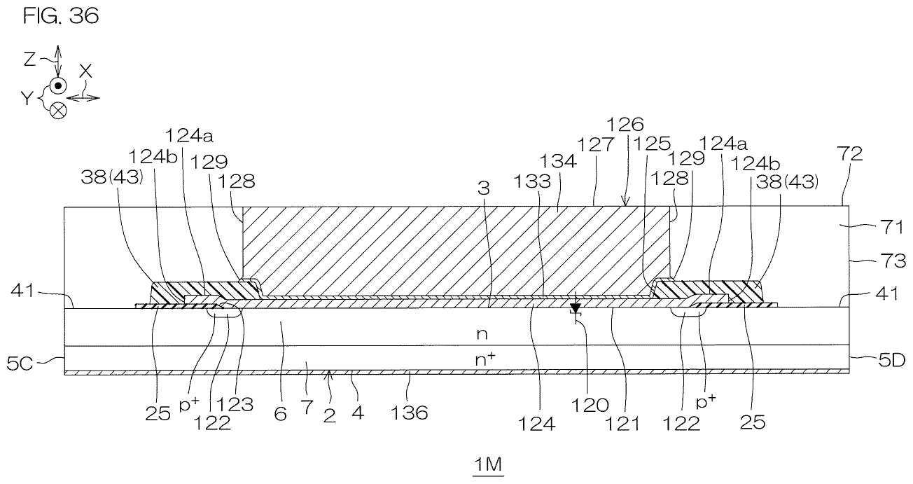

FIG. 36 is a plan view showing a semiconductor device 1M according to a thirteenth embodiment. The semiconductor device 1M has a form in which the technical idea of the semiconductor device 1C according to the third embodiment (see FIG. 18) is incorporated into the aforementioned semiconductor device 1K (see FIGS. 33 and 34). That is, the semiconductor device 1M has the single layered structure comprising the organic insulating film 43 (organic film) and includes the upper insulating film 38 that directly covers the first polar electrode 124.

The upper insulating film 38, the terminal electrode 126, and the sealing insulator 71 are formed in a similar manner to the case of the aforementioned semiconductor devices 1C and 1L and therefore the description thereof will be omitted. As described above, the same effects as those of the semiconductor device 1L are also achieved with the semiconductor device 1M.

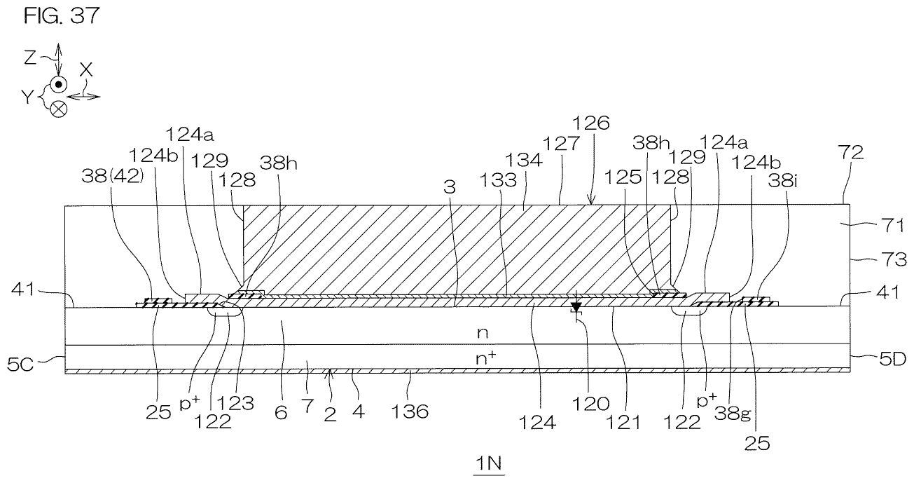

FIG. 37 is a plan view showing a semiconductor device 1N according to a fourteenth embodiment. The semiconductor device 1N has a form in which the technical idea of the semiconductor device 1D according to the fourth embodiment (see FIGS. 20 to 23) is incorporated into the aforementioned semiconductor device 1L (see FIG. 35) or the aforementioned semiconductor device 1M (see FIG. 36). That is, the semiconductor device 1N has the upper insulating film 38 that has a single layered structure comprising the inorganic insulating film 42 (inorganic film) or the organic insulating film 43 (organic film) and that directly covers the first polar electrode 124.

The upper insulating film 38 has a removal portion 38g that exposes at least a part of the corner portion of the first polar electrode 124, in this embodiment. The removal portion 38g exposes the whole region of the corner portion of the first polar electrode 124, in this embodiment. The removal portion 38g exposes the electrode surface 124a and the electrode side wall 124b at the corner portion of the first polar electrode 124.

The upper insulating film 38 has an inner covering portion 38h that is defined by the removal portion 38g on the first polar electrode 124. The inner covering portion 38h covers a peripheral edge portion of the first polar electrode 124 such as to expose the corner portion of the first polar electrode 124, and defines the diode opening 123 that exposes the inner portion of the first polar electrode 124. The inner covering portion 38h is formed in an annular shape that surrounds the inner portion of the first polar electrode 124 in plan view, in this embodiment.

The upper insulating film 38 has an outer covering portion 38i that is defined by the removal portion 38g in a region on the outside of the first polar electrode 124 (specifically, on the main surface insulating film 25). The outer covering portion 38i is formed in an annular shape that surrounds the first polar electrode 124 in plan view. The above-described dicing street 41 is defined in a region between the peripheral edge of the first main surface 3 and the outer covering portion 38i, in this embodiment.

The sealing insulator 71 directly covers the upper insulating film 38 such as to enter the removal portion 38g from on the upper insulating film 38, in this embodiment. The sealing insulator 71 directly covers at least a part of the corner portion of the first polar electrode 124 within the removal portion 38g. The sealing insulator 71 directly covers the whole region of the corner portion of the first polar electrode 124, in this embodiment. The sealing insulator 71 directly covers the electrode surface 124a and the electrode side wall 124b within the removal portion 38g.

The sealing insulator 71 directly covers the inner covering portion 38h of the upper insulating film 38 immediately above the first polar electrode 124. The sealing insulator 71 may have a portion that faces the inner covering portion 38h with the protrusion portion 129 of the terminal electrode 126 interposed therebetween. The sealing insulator 71 covers the outer covering portion 38i in a region on the outside of the first polar electrode 124. As described above, the same effects as those of the semiconductor device 1K are also achieved with the semiconductor device 1N.

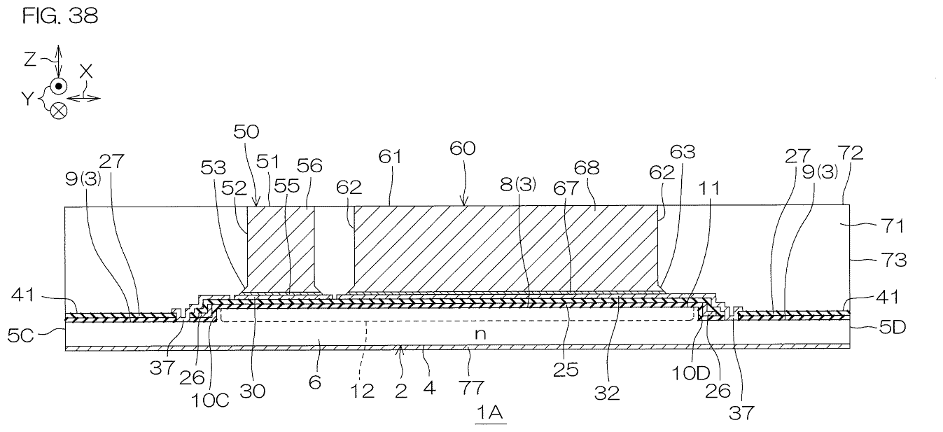

Hereinafter, modified examples to be applied to each embodiment shall be shown. FIG. 38 is a cross sectional view showing a modified example of the chip 2 to be applied to each of the embodiments. In FIG. 38, a mode in which the modified example of the chip 2 is applied to the semiconductor device 1A is shown as an example. However, the modified example of the chip 2 may be applied to any one of the second to fourteenth embodiments.

With reference to FIG. 38, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment. The chip 2 having such a structure is formed by fully removing the second semiconductor region 7 (the semiconductor substrate) in the step shown in FIG. 12H aforementioned.

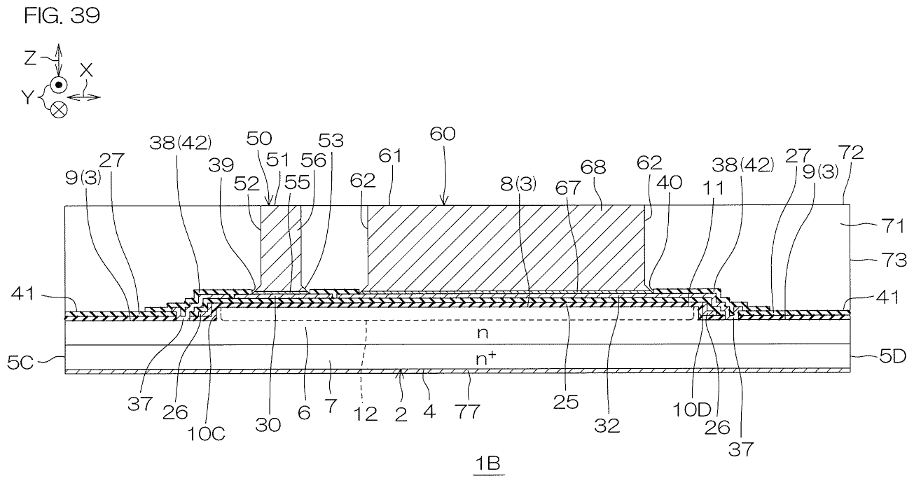

FIG. 39 is a cross sectional view showing a modified example of the sealing insulator 71 to be applied to each of the embodiments having the upper insulating film 38. In FIG. 39, a mode in which the modified example of the sealing insulator 71 is applied to the semiconductor device 1B is shown as an example. However, the modified example of the sealing insulator 71 may be applied to arbitrary embodiment having the upper insulating film 38 of any one of the second to fourteenth embodiments.

With reference to FIG. 39, the semiconductor device 1B may include the sealing insulator 71 that covers a whole region of the upper insulating film 38. In this case, in the embodiment having the upper insulating film 38 of the first to tenth embodiments, the gate terminal electrode 50 and the source terminal electrode 60 that are not in contact with the upper insulating film 38 are formed.

In this case, the sealing insulator 71 may have a portion that directly covers the gate electrode 30 and the source electrode 32. In the embodiment having the upper insulating film 38 of the eleventh to fourteenth embodiments, the terminal electrode 126 that is not in contact with the upper insulating film 38 is formed. In this case, the sealing insulator 71 may have a portion that directly covers the first polar electrode 124.

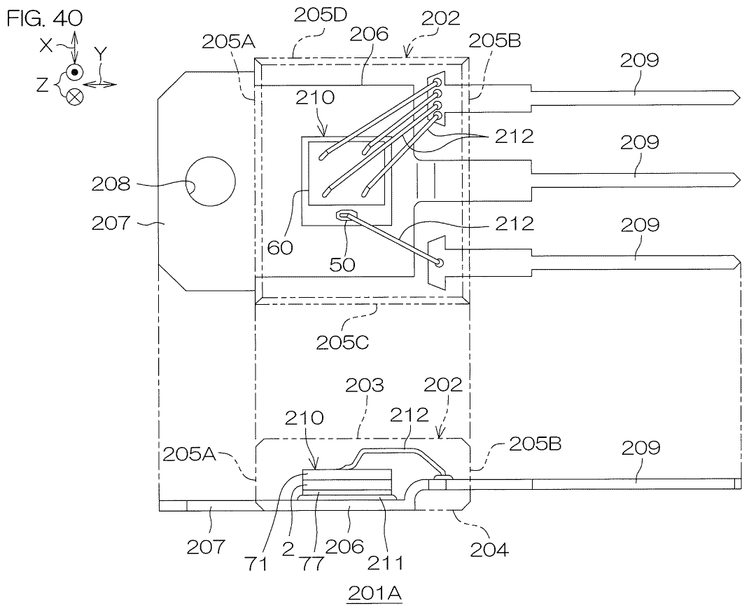

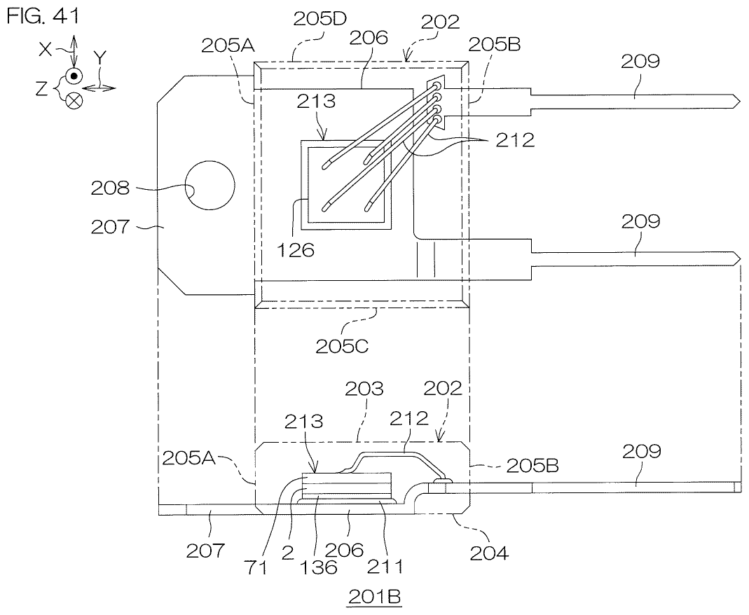

Hereinafter, configuration examples of packages to which any one or plural of the semiconductor devices 1A to 1N according to the first to fourteenth embodiments are to be incorporated shall be shown. FIG. 40 is a plan view showing a package 201A to which any one of the semiconductor devices 1A to 1J according to the first to tenth embodiments is to be incorporated. The package 201A may be referred to as a “semiconductor package” or a “semiconductor module”.

With reference to FIG. 40, the package 201A includes a package body 202 of a rectangular parallelepiped shape. The package body 202 consists of a mold resin and includes a matrix resin (for example, epoxy resin), a plurality of fillers and a plurality of flexible particles (flexible agent) as with the sealing insulator 71. The package body 202 has a first surface 203 on one side, the second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to an outside of the package body 202. The drawer board part 207 has a through hole 208 of a circular shape. The metal plate 206 may be exposed from the second surface 204.

The package 201A includes a plurality of (in this embodiment, three) lead terminals 209 that are pulled out from an inside of the package body 202 to the outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1J according to the first to tenth embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of a gold wire, a copper wire and an aluminum wire. As a matter of course, the conducting wires 212 may each consist of a metal plate such as a metal clip, instead of the metal wire.

At least one (in this embodiment, one) conducting wire 212 is electrically connected to the gate terminal electrode 50 and the lead terminal 209. At least one (in this embodiment, four) conducting wires 212 are electrically connected to the source terminal electrode 60 and the lead terminal 209. In a case in which the source terminal electrode 60 includes the sense terminal electrode 103 (see FIG. 25), the lead terminal 209 corresponding to the sense terminal electrode 103, and the conducting wire 212 corresponding to the sense terminal electrode 103 and the lead terminals 209 may be provided.

FIG. 41 is a plan view showing a package 201B to which any one of the semiconductor devices 1K to 1N according to the eleventh to fourteenth embodiments is to be incorporated. The package 201B may be referred to as a “semiconductor package” or a “semiconductor module”. With reference to FIG. 41, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of any one of the semiconductor devices 1K to 1N according to the eleventh to fourteenth embodiments. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal electrode 126 and the lead terminal 209.

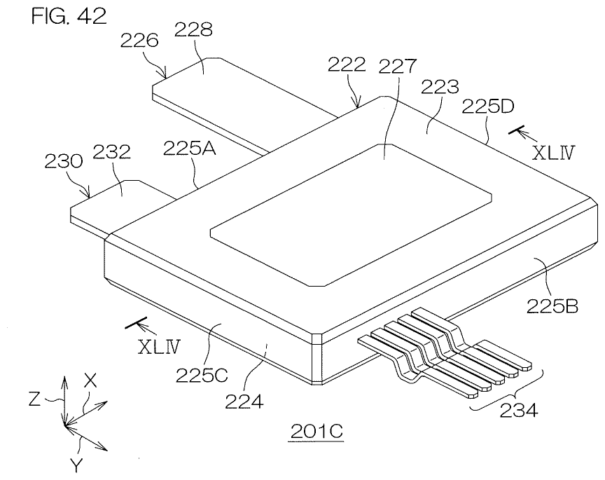

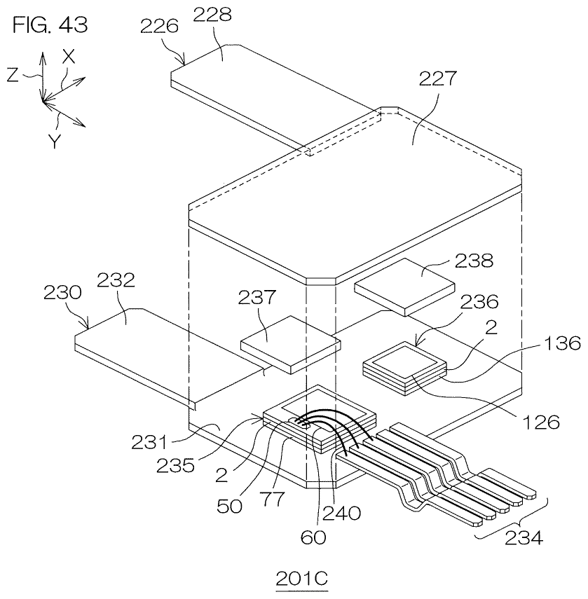

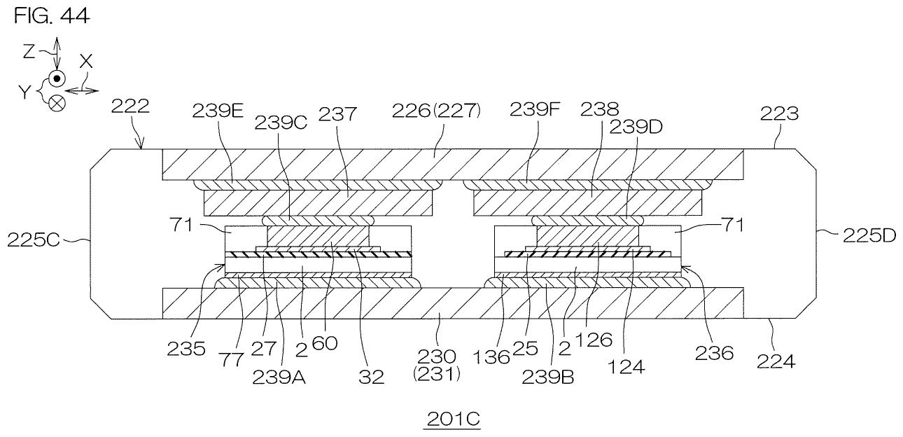

FIG. 42 is a perspective view showing a package 201C to which any one of the semiconductor devices 1A to 1J according to the first to tenth embodiments and the semiconductor device 1K to 1N according to the eleventh to fourteenth embodiment are to be incorporated. FIG. 43 is an exploded perspective view of the package 201C shown in FIG. 42. FIG. 44 is a cross sectional view taken along XLIV-XLIV line shown in FIG. 42. The package 201C may be referred to as a “semiconductor package” or a “semiconductor module”.

With reference to FIG. 42 to FIG. 44, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, the second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes a second pad portion 231 and a second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1J according to the first to tenth embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of any one of the semiconductor devices 1K to 1N according to the eleventh to fourteenth embodiments. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal electrode 60 and the first conductor spacer 237, and connects the first conductor spacer 237 to the source terminal electrode 60. The fourth conductive adhesive 239D is interposed between the terminal electrode 126 and the second conductor spacer 238, and connects the second conductor spacer 238 to the terminal electrode 126.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal electrode 50 of the first semiconductor device 235 and at least one (in this embodiment, a plurality of) third lead terminals 234 inside the package body 222. The conducting wires 240 each consists of a metal wire (that is, bonding wire), in this embodiment.

The conducting wires 240 may include at least one of a gold wire, a copper wire and an aluminum wire. As a matter of course, the conducting wires 240 may each consist of a metal plate such as a metal clip, instead of the metal wire. In a case in which the source terminal electrode 60 includes the sense terminal electrode 103 (see FIG. 15), a conducting wire 240 to be connected to the sense terminal electrode 103 and the third lead terminal 234 may be further provide.

An example in which the source terminal electrode 60 is connected to the first pad portion 227 via the first conductor spacers 237 has been shown, in this embodiment. However, the source terminal electrode 60 may be connected to the first pad portion 227 by the third conductive adhesive 239C without the first conductor spacer 237. Also, an example in which the terminal electrode 126 is connected to the first pad portion 227 via the second conductor spacers 238 has been shown, in this embodiment. However, the terminal electrode 126 may be connected to the first pad portion 227 by the fourth conductive adhesive 239D without the second conductor spacers 238.

Each of the above embodiments can be implemented in yet other embodiments. For example, features disclosed in the first to fourteenth embodiments aforementioned can be appropriately combined therebetween. That is, a configuration that includes at least two features among the features disclosed in the first to fourteenth embodiments aforementioned at the same time may be adopted.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.
[A1] A semiconductor device (1A to 1N) comprising: a chip (2) that has a main surface (3); a main surface electrode (30, 32, 124) that is arranged on the main surface (3); a terminal electrode (50, 60, 126) that is arranged on the main surface electrode (30, 32, 124) such as to expose a part of the main surface electrode (30, 32, 124); and a sealing insulator (71) that covers a periphery of the terminal electrode (50, 60, 126) such as to expose a part of the terminal electrode (50, 60, 126), and that has a portion directly covering the main surface electrode (30, 32, 124).
[A2] The semiconductor device (1A to 1N) according to A1, wherein the sealing insulator (71) includes resin and a plurality of fillers.
[A3] The semiconductor device (1A to 1N) according to A2, wherein the resin consists of a thermosetting resin.
[A4] The semiconductor device (1A to 1N) according to any one of A1 to A3, wherein the terminal electrode (50, 60, 126) is thicker than the chip (2), and the sealing insulator (71) is thicker than the chip (2).
[A5] The semiconductor device (1A to 1N) according to any one of A1 to A4, wherein the terminal electrode (50, 60, 126) exposes a corner portion of the main surface electrode (30, 32, 124), and the sealing insulator (71) directly covers the corner portion of the main surface electrode (30, 32, 124).
[A6] The semiconductor device (1A to 1N) according to any one of A1 to A5, wherein the main surface electrode (30, 32, 124) has an electrode surface (30a, 32a, 124a) and an electrode side wall (30b, 32b, 124b), the terminal electrode (50, 60, 126) exposes the electrode surface (30a, 32a, 124a) and the electrode side wall (30b, 32b, 124b), and the sealing insulator (71) directly covers the electrode surface (30a, 32a, 124a) and the electrode side wall (30b, 32b, 124b).
[A7] The semiconductor device (1A to 1N) according to any one of A1 to A6, wherein the sealing insulator (71) has a portion in contact only with the main surface electrode (30, 32, 124) and the terminal electrode (50, 60, 126) on the main surface electrode (30, 32, 124).
[A8] The semiconductor device (1A to 1N) according to any one of A1 to A7, wherein the terminal electrode (50, 60, 126) has a terminal surface (51, 61, 127), and the sealing insulator (71) has an insulating main surface (72) that forms a single flat surface with the terminal surface (51, 61, 127).
[A9] The semiconductor device (1A to 1N) according to any one of A1 to A8, wherein the chip (2) has a side surface (5A to 5D), and the sealing insulator (71) has an insulating side wall (73) that forms a single flat surface with the side surface (5A to 5D).
[A10] The semiconductor device (1A to 1N) according to any one of A1 to A9, wherein the chip (2) includes a monocrystal of a wide bandgap semiconductor.
[A11] A semiconductor device (1A to 1N) comprising: a chip (2) that has a main surface (3); a main surface electrode (30, 32, 124) that is arranged on the main surface (3); an insulating film (38) that has a single layered structure comprising an inorganic film (42) or an organic film (43), and that directly covers the main surface electrode (30, 32, 124) such as to expose a part of the main surface electrode (30, 32, 124); a terminal electrode (50, 60, 126) that is arranged on the main surface electrode (30, 32, 124); and a sealing insulator (71) that covers a periphery of the terminal electrode (50, 60, 126) such as to expose a part of the terminal electrode (50, 60, 126), and that has a portion directly covering the insulating film (38).
[A12] The semiconductor device (1A to 1N) according to A11, wherein the sealing insulator (71) includes resin and a plurality of fillers.
[A13] The semiconductor device (1A to 1N) according to A11 or A12, wherein the insulating film (38) has a single layered structure comprising an oxide film, a nitride film, an oxynitride film, or a photosensitive resin film.
[A14] The semiconductor device (1A to 1N) according to any one of A11 to A13, wherein the terminal electrode (50, 60, 126) is thicker than the chip (2), and the sealing insulator (71) is thicker than the chip (2).
[A15] The semiconductor device (1A to 1N) according to any one of A11 to A14, wherein the insulating film (38) directly covers at least a part of a corner portion of the main surface electrode (30, 32, 124), and the sealing insulator (71) covers at least a part of the corner portion of the main surface electrode (30, 32, 124) with the insulating film (38) interposed therebetween.
[A16] The semiconductor device (1A to 1N) according to any one of A11 to A15, wherein the main surface electrode (30, 32, 124) has an electrode surface (30a, 32a, 124a) and an electrode side wall (30b, 32b, 124b), the insulating film (38) directly covers the electrode surface (30a, 32a, 124a) and the electrode side wall (30b, 32b, 124b), and the sealing insulator (71) covers the electrode surface (30a, 32a, 124a) and the electrode side wall (30b, 32b, 124b) with the insulating film (38) interposed therebetween.
[A17] The semiconductor device (1A to 1N) according to any one of A11 to A16, wherein the terminal electrode (50, 60, 126) has a portion that is positioned on the main surface electrode (30, 32, 124) and a portion that is positioned on the insulating film (38).
[A18] The semiconductor device (1A to 1N) according to any one of A11 to A17, wherein the terminal electrode (50, 60, 126) has a terminal surface (51, 61, 127), and the sealing insulator (71) has an insulating main surface (72) that forms a single flat surface with the terminal surface (51, 61, 127).
[A19] The semiconductor device (1A to 1N) according to any one of A11 to A18, wherein the chip (2) has a side surface (5A to 5D), and the sealing insulator (71) has an insulating side wall (73) that forms a single flat surface with the side surface (5A to 5D).
[A20] The semiconductor device (1A to 1N) according to any one of A11 to A19, wherein the chip (2) includes a monocrystal of a wide bandgap semiconductor.
[B1] A manufacturing method for a semiconductor device (1A to 1N) comprising: a step of preparing a wafer structure (80) that includes a wafer (81) having a main surface (82), and a main surface electrode (30, 32, 124) arranged on the main surface (82); a step of forming a terminal electrode (50, 60, 126) on the main surface electrode (30, 32, 124) such as to expose a part of the main surface electrode (30, 32, 124); and a step of forming a sealing insulator (71) that covers a periphery of the terminal electrode (50, 60, 126) such as to expose a part of the terminal electrode (50, 60, 126), and that has a portion directly covering the main surface electrode (30, 32, 124).
[B2] The manufacturing method for the semiconductor device (1A to 1N) according to B1, wherein the step of forming a sealing insulator (71) includes a step of supplying sealant (93) including a resin onto the main surface electrode (30, 32, 124).
[B3] The manufacturing method for the semiconductor device (1A to 1N) according to B2, wherein the sealant (93) includes a thermosetting resin as the resin.
[B4] The manufacturing method for the semiconductor device (1A to 1N) according to B2 or B3, wherein the sealant (93) includes a plurality of fillers that are added to the resin.
[B5] The manufacturing method for the semiconductor device (1A to 1N) according to any one of B1 to B4, wherein the step of forming the terminal electrode (50, 60, 126) includes the step of forming the terminal electrode (50, 60, 126) that exposes at least a part of a corner portion of the main surface electrode (30, 32, 124), and the step of forming the sealing insulator (71) includes the step of forming the sealing insulator (71) that directly covers at least a part of the corner portion of the main surface electrode (30, 32, 124).
[B6] The manufacturing method for the semiconductor device (1A to 1N) according to any one of B1 to B5, wherein the step of forming the terminal electrode (50, 60, 126) includes the step of forming the terminal electrode (50, 60, 126) that exposes an electrode surface (30a, 32a, 124a) and an electrode side wall (30b, 32b, 124b) of the main surface electrode (30, 32, 124), and the step of forming the sealing insulator (71) includes the step of forming the sealing insulator (71) that directly covers the electrode surface (30a, 32a, 124a) and the electrode side wall (30b, 32b, 124b) of the main surface electrode (30, 32, 124).
[B7] The manufacturing method for the semiconductor device (1A to 1N) according to any one of B1 to B6, wherein the step of forming the sealing insulator (71) includes the step of forming the sealing insulator (71) that has a portion in contact only with the main surface electrode (30, 32, 124) and the terminal electrode (50, 60, 126) on the main surface electrode (30, 32, 124).
[B8] The manufacturing method for the semiconductor device (1A to 1N) according to any one of B1 to B7, wherein the step of forming the sealing insulator (71) includes the step of forming the sealing insulator (71) that has an insulating main surface (72) that forms a single flat surface with a terminal surface (51, 61, 127) of the terminal electrode (50, 60, 126).
[B9] The manufacturing method for the semiconductor device (1A to 1N) according to any one of B1 to B8, further comprising: a step of thinning the wafer (81) such as to have a thickness less than that of the sealing insulator (71) after the step of forming a sealing insulator (71).
[B10] The manufacturing method for the semiconductor device (1A to 1N) according to any one of B1 to B9, further comprising: a step of preparing the wafer structure (80) that includes the wafer (81) having the main surface (82) in which a device region (86) and a scheduled cutting line (87) defining the device region (86) are set, and the main surface electrode (30, 32, 124) arranged on the main surface (82) in the device region (86); and a step of cutting the wafer (81) and the sealing insulator (71) along the scheduled cutting line (87) after the step of forming the sealing insulator (71).
[B11] The manufacturing method for the semiconductor device (1A to 1N) according to any one of B1 to B10, wherein the wafer (81) includes a monocrystal of a wide bandgap semiconductor.
[C1] A manufacturing method for a semiconductor device (1A to 1N) comprising: a step of preparing a wafer structure (80) that includes a wafer (81) having a main surface (82) and a main surface electrode (30, 32, 124) arranged on the main surface (82); a step of forming an insulating film (38) that has a single layered structure comprising an inorganic film (42) or an organic film (43), and that directly covers the main surface electrode (30, 32, 124) such as to expose a part of the main surface electrode (30, 32, 124); a step of forming a terminal electrode (50, 60, 126) on the main surface electrode (30, 32, 124); and a step of forming a sealing insulator (71) that covers a periphery of the terminal electrode (50, 60, 126) such as to expose a part of the terminal electrode (50, 60, 126), and that has a portion directly covering the insulating film (38).
[C2] The manufacturing method for the semiconductor device (1A to 1N) according to C1, wherein the step of forming the sealing insulator (71) includes a step of supplying a sealant (93) that includes a resin onto the insulating film (38).
[C3] The manufacturing method for the semiconductor device (1A to 1N) according to C2, wherein the sealant (93) includes a thermosetting resin as the resin.
[C4] The manufacturing method for the semiconductor device (1A to 1N) according to C2 or C3, wherein the sealant (93) includes a plurality of fillers that are added to the resin.
[C5] The manufacturing method for the semiconductor device (1A to 1N) according to any one of C1 to C4, wherein the step of forming the insulating film (38) includes the step of forming the insulating film (38) that has a single layered structure comprising an oxide film, a nitride film, an oxynitride film, or a photosensitive resin film.
[C6] The manufacturing method for the semiconductor device (1A to 1N) according to any one of C1 to C5, wherein the step of forming the insulating film (38) includes the step of forming the insulating film (38) that directly covers at least a part of a corner portion of the main surface electrode (30, 32, 124), and the step of forming the sealing insulator (71) includes the step of forming the sealing insulator (71) that covers at least a part of the corner portion of the main surface electrode (30, 32, 124) with the insulating film (38) interposed therebetween.
[C7] The manufacturing method for the semiconductor device (1A to 1N) according to any one of C1 to C6, wherein the step of forming the insulating film (38) includes the step of forming the insulating film (38) that directly covers an electrode surface (30a, 32a, 124a) and an electrode side wall (30b, 32b, 124b) of the main surface electrode (30, 32, 124), and the step of forming the sealing insulator (71) includes the step of forming the sealing insulator (71) that covers the electrode surface (30a, 32a, 124a) and the electrode side wall (30b, 32b, 124b) of the main surface electrode (30, 32, 124) with the insulating film (38) interposed therebetween.
[C8] The manufacturing method for the semiconductor device (1A to 1N) according to any one of C1 to C7, wherein the step of forming the terminal electrode (50, 60, 126) includes the step of forming the terminal electrode (50, 60, 126) that has a portion positioned on the main surface electrode (30, 32, 124) and a portion positioned on the insulating film (38).
[C9] The manufacturing method for the semiconductor device (1A to 1N) according to any one of C1 to C8, wherein the step of forming the sealing insulator (71) includes the step of forming the sealing insulator (71) that has a portion directly covering the insulating film (38) and the terminal electrode (50, 60, 126) on the main surface electrode (30, 32, 124).
[C10] The manufacturing method for the semiconductor device (1A to 1N) according to any one of C1 to C9, wherein the step of forming the sealing insulator (71) includes the step of forming the sealing insulator (71) that has an insulating main surface (72) that forms a single flat surface with a terminal surface (51, 61, 127) of the terminal electrode (50, 60, 126).
[C11] The manufacturing method for the semiconductor device (1A to 1N) according to any one of C1 to C10, further comprising: a step of thinning the wafer (81) such as to have a thickness less than that of the sealing insulator (71) after the step of forming the sealing insulator (71).
[C12] The manufacturing method for the semiconductor device (1A to 1N) according to any one of C1 to C11, further comprising: the step of preparing the wafer structure (80) that includes the wafer (81) having the main surface (82) in which a device region (86) and a scheduled cutting line (87) defining the device region (86) are set, and the main surface electrode (30, 32, 124) arranged on the main surface (82) in the device region (86); and a step of cutting the wafer (81) and the sealing insulator (71) along the scheduled cutting line (87) after the step of forming the sealing insulator (71).
[C13] The manufacturing method for the semiconductor device (1A to 1N) according to any one of C1 to C12, wherein the wafer (81) includes a monocrystal of a wide bandgap semiconductor.

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A semiconductor device comprising:
a chip that has a main surface;
a main surface electrode that is arranged on the main surface;
a terminal electrode that is arranged on the main surface electrode such as to expose a part of the main surface electrode; and
a sealing insulator that covers a periphery of the terminal electrode such as to expose a part of the terminal electrode, and that has a portion directly covering the main surface electrode.

2. The semiconductor device according to claim 1,
wherein the sealing insulator includes resin and a plurality of fillers.

3. The semiconductor device according to claim 2,
wherein the resin consists of a thermosetting resin.

4. The semiconductor device according to claim 1,
wherein the terminal electrode is thicker than the chip, and
the sealing insulator is thicker than the chip.

5. The semiconductor device according to claim 1,
wherein the terminal electrode exposes a corner portion of the main surface electrode, and
the sealing insulator directly covers the corner portion of the main surface electrode.

6. The semiconductor device according to claim 1,
wherein the main surface electrode has an electrode surface and an electrode side wall,
the terminal electrode exposes the electrode surface and the electrode side wall, and
the sealing insulator directly covers the electrode surface and the electrode side wall.

7. The semiconductor device according to claim 1,
wherein the sealing insulator has a portion in contact only with the main surface electrode and the terminal electrode on the main surface electrode.

8. The semiconductor device according to claim 1,
wherein the terminal electrode has a terminal surface, and
the sealing insulator has an insulating main surface that forms a single flat surface with the terminal surface.

9. The semiconductor device according to claim 1,
wherein the chip has a side surface, and
the sealing insulator has an insulating side wall that forms a single flat surface with the side surface.

10. The semiconductor device according to claim 1,
wherein the chip includes a monocrystal of a wide bandgap semiconductor.

11. A semiconductor device comprising:
a chip that has a main surface;
a main surface electrode that is arranged on the main surface;
an insulating film that has a single layered structure comprising an inorganic film or an organic film, and that directly covers the main surface electrode such as to expose a part of the main surface electrode;
a terminal electrode that is arranged on the main surface electrode; and
a sealing insulator that covers a periphery of the terminal electrode such as to expose a part of the terminal electrode, and that has a portion directly covering the insulating film.

12. The semiconductor device according to claim 11,
wherein the sealing insulator includes resin and a plurality of fillers.

13. The semiconductor device according to claim 11,
wherein the insulating film has a single layered structure comprising an oxide film, a nitride film, an oxynitride film, or a photosensitive resin film.

14. The semiconductor device according to claim 11,
wherein the terminal electrode is thicker than the chip, and
the sealing insulator is thicker than the chip.

15. The semiconductor device according to claim 11,
wherein the insulating film directly covers at least a part of a corner portion of the main surface electrode, and
the sealing insulator covers at least a part of the corner portion of the main surface electrode across the insulating film.

16. The semiconductor device according to claim 11,
wherein the main surface electrode has an electrode surface and an electrode side wall,
the insulating film directly covers the electrode surface and the electrode side wall, and
the sealing insulator covers the electrode surface and the electrode side wall across the insulating film.

17. The semiconductor device according to claim 11,
wherein the terminal electrode has a portion that is positioned on the main surface electrode and a portion that is positioned on the insulating film.

18. The semiconductor device according to claim 11,
wherein the terminal electrode has a terminal surface, and
the sealing insulator has an insulating main surface that forms a single flat surface with the terminal surface.

19. The semiconductor device according to claim 11,
wherein the chip has a side surface, and
the sealing insulator has an insulating side wall that forms a single flat surface with the side surface.

20. The semiconductor device according to claim 11,
wherein the chip includes a monocrystal of a wide bandgap semiconductor.
